(19) United States
(12) Patent Application Publication
(10) Pub. No.: US 2025/0006459 A1
(43) Pub. Date: Jan. 2, 2025

(54) METHOD FOR DETERMINING A DISTORTION-CORRECTED POSITION OF A FEATURE IN AN IMAGE IMAGED WITH A MULTI-BEAM CHARGED PARTICLE MICROSCOPE, CORRESPONDING COMPUTER PROGRAM PRODUCT AND MULTI-BEAM CHARGED PARTICLE MICROSCOPE

(71) Applicant: Carl Zeiss MultiSEM GmbH, Oberkochen (DE)

(72) Inventors: Daniel Weiss, Essingen-Forst (DE); Nicolas Kaufmann, Aalen (DE); Dirk Zeidler, Oberkochen (DE)

(21) Appl. No.: 18/783,650

(22) Filed: Jul. 25, 2024

Related U.S. Application Data
(63) Continuation of application No. PCT/EP2023/025023, filed on Jan. 20, 2023.

(30) Foreign Application Priority Data
Feb. 3, 2022 (DE) 10 2022 102 548.9

(51) Int. Cl. H01J 37/317; G06N 20/10; G06T 5/20; G06T 5/80; H01J 37/147; H01J 37/153; H01J 37/22; H01J 37/244; H01J 37/28

(52) U.S. Cl. CPC H01J 37/3177; G06N 20/10; G06T 5/20; G06T 5/80; H01J 37/1474; H01J 37/153; H01J 37/222; H01J 37/244; H01J 37/28; G06T 2207/10061; H01J 2237/1534; H01J 2237/2448; H01J 2237/30488

(57) ABSTRACT

A method for determining a distortion-corrected position of a feature in an image that is composed of one or a plurality of image patches, each image patch being composed of a plurality of image subfields, each image subfield being imaged with a related beamlet of a multi-beam charged particle microscope, respectively, comprises: a) providing a plurality of vector distortion maps for each image subfield, respectively, each vector distortion map characterizing the position dependent distortion for each pixel of the related image subfield; b) identifying a feature of interest in the image; c) extracting a geometric characteristic of the feature; d) determining a corresponding image subfield comprising the extracted geometric characteristic of the feature; e) determining a position or positions of the extracted geometric characteristic of the feature within the determined corresponding image subfield; and f) correcting the position or positions of the extracted geometric characteristic in the image.

### CROSS-REFERENCE TO RELATED APPLICATIONS

The present application is a continuation of, and claims benefit under 35 USC 120 to, international application No. PCT/EP2023/025023, filed Jan. 20, 2023, which claims benefit under 35 USC 119 of German Application No. 10 2022 102 548.9, filed Feb. 3, 2022. The entire disclosure of each of these applications is incorporated by reference herein.

### FIELD

The present disclosure relates to the field of multi-beam charged particle microscopes and to related inspections tasks. For example, the present disclosure relates to a method for determining a distortion-corrected position of a feature in an image that is composed of one or a plurality of image patches wherein each image patch is composed of a plurality of image subfields, wherein each image subfield is imaged with a related beamlet of the multi-beam charged particle microscope, respectively. The present disclosure also relates to a corresponding computer program product and to a corresponding multi-beam charged particle microscope.

### BACKGROUND

With the continuous development of ever smaller and more sophisticated microstructures such as semiconductor devices, there is a desire for further development and optimization of planar fabrication techniques and inspection systems for fabrication and inspection of the small dimensions of the microstructures. Development and fabrication of the semiconductor devices involves for example design verification of test wafers, and the planar fabrication techniques involves process optimization for reliable high throughput fabrication. In addition, recently the analysis of semiconductor wafers for reverse engineering and customized, individual configuring of semiconductor devices is used. High throughput inspection tools for the examination of the microstructures on wafers with high accuracy are therefore demanded.

Typical silicon wafers used in manufacturing of semiconductor devices have diameters of up to 12 inches (300 mm). Each Wafer is segmented in 30-60 repetitive areas (“Dies”) of about up to 800 sq mm size. A semiconductor device comprises a plurality of semiconductor structures fabricated in layers on a surface of the wafer by planar integration techniques. Due to the fabrication processes involved, semiconductor wafers have typically a flat surface. The feature size of the integrated semiconductor structures extends between few μm down to the critical dimensions (CD) of 5 nm, with even decreasing features sizes in near future, for example feature sizes or critical dimensions (CD) below 3 nm, for example 2 nm, or even below 1 nm. With the small structure sizes mentioned above, defects of the size of the critical dimensions are identified in a very large area (relative to structure size) in a short time. For several applications, the specification for accuracy of a measurement provided by an inspection device is even higher, for example a factor of two or an order of magnitude. For example, a width of a semiconductor feature is measured with an accuracy below 1 nm, for example 0.3 nm or even less, and a relative position of semiconductor structures is determined with an overlay accuracy of below 1 nm, for example 0.3 nm or even less.

A recent development in the field of charged particle microscopes (CPM) is the multi beam charged particle microscope (MSEM). A multi beam scanning electron microscope is disclosed, for example, in U.S. Pat. No. 7,244,949 and in US20190355544. In a multi beam electron microscope, a sample is irradiated by an array of electron beamlets, comprising for example 4 up to 10000 electron beams, as primary radiation, whereby each electron beam is separated by a distance of 1-200 micrometers from its next neighboring electron beam. For example, a multi beam charged particle microscope has about 100 separated electron beams or beamlets, arranged on a hexagonal array, with the electron beamlets separated by a distance of about 10 μm. The plurality of primary charged particle beamlets is focused by a common objective lens on a surface of a sample under investigation, for example a semiconductor wafer fixed on a wafer chuck, which is mounted on a movable stage. During the illumination of the wafer surface with primary charged particle beamlets, interaction products, e.g. secondary electrons, originate from the plurality of intersection points formed by the focus points of the primary charged particle beamlets, while the amount and energy of interaction products depend on the material composition and topography of the wafer surface. The interaction products form a plurality of secondary charged particle beamlets, which is collected by the common objective lens and guided onto a detector arranged at a detector plane by a projection imaging system of the multi-beam inspection system. The detector comprises a plurality of detection areas with each comprising a plurality of detection pixels and detects an intensity distribution for each of the plurality of secondary charged particle beamlets and an image patch of for example 100 μm×100 μm is obtained. Certain known multi-beam charged particle microscopes comprise a sequence of electrostatic and magnetic elements. At least some of the electrostatic and magnetic elements are adjustable to adjust focus position and stigmation of the plurality of secondary charged particle beams.

Certain known multi-beam charged particle microscopes comprise at least one cross over plane of the primary or for the secondary charged particles. Certain known multi-beam charged particle microscopes comprise detection systems to facilitate the adjustment. Certain known multi-beam charged particle microscopes comprise at least a deflection scanner for collectively scanning the plurality of primary charged particle beamlets over an area of a sample surface to obtain an image patch of the sample surface. More details of a multi-beam charged particle microscope and method of operating a multi-beam charged particle microscope are described, for example, in PCT/EP2021/061216, filed on Apr. 29, 2021, which is hereby incorporated by reference.

In charged particle microscopes for wafer inspection, it is desired to maintain imaging conditions stable, such that imaging can be performed with high reliability and high repeatability. The throughput generally depends on several parameters, for example speed of the stage and re-alignment at new measurement sites, as well as the measured area per acquisition time itself. The latter is generally determined by dwell time, resolution and the number of beamlets. In addition, for a multi-beam charged particle microscope, time consuming image postprocessing is used, for example the signal generated by the detection system of the multi-beam charged particle microscope is digitally corrected, before the image patch is stitched together from a plurality of image subfields.

The plurality of primary charged particle beamlets can deviate from the regular raster positions within a raster configuration, for example a hexagonal raster configuration. In addition, the plurality of primary charged particle beamlets can deviate from the regular raster positions of a raster scanning operation within the planar area segment, and the resolution of the multi-beam charged particle inspection system can be different and depend on the individual scan position of each individual beamlet of the plurality of primary charged particle beamlets. With a plurality of primary charged particle beamlets, each beamlet is incident on the intersection volume of a common scanning deflector at a different angle, and each beamlet is deflected to a different exiting angle, and each beamlet is traversing the intersection volume of a common scanning deflector on a different path. Therefore, each beamlet experiences a different distortion pattern during scanning operation. Certain single-beam dynamic correctors are unsuitable to mitigate any scanning induced distortion of a plurality of primary beamlets. US20090001267 A1 illustrates the calibration of a primary-beam layout or static raster pattern configuration of a multi beam charged particle system comprising five primary charged particle beamlets. Three causes of deviations of the raster pattern are illustrated: rotation of the primary-beam layout, scaling up or down of the primary-beam layout, a shift of the whole primary-beam layout. US20090001267 A1 therefore considers the basic first order distortion (rotation, magnification, global shift or displacement) of the static primary-beam raster pattern, formed by the static focus points of the plurality of primary beamlets. In addition, US20090001267 A1 includes the calibration of the first order properties of the collective raster scanner, the deflection width and the deflection direction for collectively raster scanning the plurality of primary beamlets. A mechanism for compensating these basic errors in the primary-beam layout are discussed. No solutions are provided for higher order distortions of the static raster patterns, for example third order distortion. Even after calibration of the primary beam layout and optionally also the secondary electron beam path, scanning distortions are introduced during scanning in each individual primary beamlet, which are not addressed by calibration of the static raster pattern of the plurality of primary beamlets.

Often, the basic first order image distortions (rotation, magnification and global shift or displacement) are corrected in today's high-tech multi-beam charged particle microscopes. However, with the increasing demand for better accuracy of measurements with an MSEM in metrology, the higher order distortions which originate from the scanning process are becoming of bigger importance and they have to be taken into appropriate consideration.

International patent application PCT/EP2021/066255 filed on Jun. 16, 2021 (published as WO2022262970A1) deals with a minimization of scanning induced distortion differences between the plurality of primary charged particle beamlets, the disclosure of the patent application being incorporated into the present patent application in its entirety by reference. The international patent application takes the approach to minimize scanning-induced distortion by improving the raster scanner arrangement itself. Such an improved raster scanning arrangement is normally only implemented in a newly built multi-beam charged particle microscope. When working with already existing microscopes, the demand for better accuracy also exists, such as when dealing with inspection tasks of quantitative metrology, for example when determining feature sizes of integrated semiconductor structures.

WO 2021/239380 A1 (corresponding to PCT/EP2021/061216 as mentioned above) discloses a multi-beam charged particle inspection system and a method of operating a multi-beam charged particle inspection system for wafer inspection with high throughput and with high resolution and high reliability. The method and the multi-beam charged particle beam inspection system are configured to extract from a plurality of sensor data a set of control signals to control the multi-beam charged particle beam inspection system and thereby maintain the imaging specifications including a movement of a wafer stage during the wafer inspection task. WO 2021/139380 A1 does not overcome the issue of time-consuming image postprocessing. Furthermore, WO 2021/139380 A1 does neither deal with a scanning-induced distortion, nor with any specific problems occurring due to a scanning-induced distortion.

### SUMMARY

The present disclosure seeks to provide an alternative solution for correcting scanning-induced distortion in images taken with multi-beam charged particle microscopes. For example, the solution shall be suited for accurately determining feature sizes of integrated semiconductor structures.

The present disclosure seeks to provide a charged particle system and method of operation of a charged particle system with high throughput, that allows a high precision measurement of semiconductor features with an accuracy below 1 nm, below 0.3 nm or even 0.1 nm.

Contrary to the hardware/physical approach taken in PCT/EP2021/066255, the present disclosure takes an algorithmic approach.

According to a first embodiment of the disclosure, the scanning-induced distortion is corrected during image postprocessing. The distortion correction is carried out based on an already existing scanning-distorted image, for example with a PC. Still, the correction is neither time-consuming, nor energy-consuming, but provides an elegant solution for specific inspection tasks.

According to a second embodiment of the disclosure, the distortion correction is carried out during image preprocessing. It is carried out with a specifically configured or programmed hardware component of the MSEM. Thus, this MSEM is an MSEM with integrated distortion correction.

The first and second embodiments can be combined with one another.

According to a first aspect, the disclosure is directed to a method for determining a distortion-corrected position of a feature in an image that is composed of one or a plurality of image patches, each image patch being composed of a plurality of image subfields, each image subfield being imaged with a related beamlet of a multi-beam charged particle microscope, respectively, the method comprising the following steps:
a) providing a plurality of vector distortion maps for each image subfield, respectively, each vector distortion map characterizing the position dependent distortion for each pixel of the related image subfield;
b) identifying a feature of interest in the image;
c) extracting a geometric characteristic of the feature;
d) determining a corresponding image subfield comprising the extracted geometric characteristic of the feature;
e) determining a position or positions of the extracted geometric characteristic of the feature within the determined corresponding image subfield; and
f) correcting the position or positions of the extracted geometric characteristic in the image based on the vector distortion map of the corresponding image subfield, thus creating distortion-corrected image data.

Normally, an image comprises a plurality of image patches; however, the method also works if the image only comprises one image “patch”. In any case, the image patch comprises a plurality of image subfields, wherein each image subfield is imaged or has been imaged with a related beamlet of a multi-beam particle microscope.

The method can be implemented to correct scanning-induced distortion which is a high precision correction. A vector distortion map can be provided for each image subfield individually, because the scanning induced distortion normally varies from subfield to subfield-which is also the reason for the fact that the scanning-induced distortion cannot be compensated with a normal collective raster scanner for all beamlets simultaneously (see above). The vector distortion map is not necessarily provided as a “map”. The term “map” shall only indicate that a distortion is a vector and that this vector is location dependent. Consequently, the vector distortion map can be a vector field.

To describe the position of a distortion vector in the image subfield, internal coordinates of the image subfield are used (normally termed p, q within the present patent application). Furthermore, the internal coordinates have to be connected to a global coordinate system (normally termed x, y within the present patent application). The position of each subfield labelled with the indices nm with respect to the global coordinate system can for example be the position of the midpoint of each subfield (p0, q0) in the global coordinate system (xnm, ynm).

The vector distortion map for each subfield and thus for each beamlet can be determined in advance. Its determination will be described more fully below. Normally, vector distortion maps will stay valid for several imaging procedures. Therefore, contrary to WO 2021/239380 A1, the disclosure can be suited for the correction of regularly or constantly occurring distortions and, for example, regularly occurring scanning-induced distortions. However, the vector distortion maps according to the disclosure can also be regularly updated. This also allows a correction of more unforeseen or irregular distortions during image post-processing.

The method steps b) identifying a feature of interest in the image and c) extracting a geometric characteristic of the feature can be carried out separately or they can be combined with one another. In general, a feature of interest can be a feature of any type and of any shape. When investigating semiconductor structures, examples for features of interest are HAR structures (high-aspect ratio structures, also called pillars or holes or contact channels) or other features.

A geometric characteristic of a feature can for example be the contour of the feature. It can alternatively be just parts of the contour, for example an edge or a corner. In general, also a pixel as such can represent a feature. According to an embodiment, the geometric characteristic of the feature is at least one of following: a contour, an edge, a corner, a point, a line, a circle, an ellipse, a center, a diameter, a radius, a distance.

Image data are generally the data of interest to be measured, for example a center or edge position, a dimension, an area, or a volume of an object of interest, or a distance or gap between several objects of interest. Further image data can also comprise a property, such as a line edge roughness, an angle between two lines, a radius or the like.

Feature extraction as such is well known in image processing. Examples for contour extraction may be found in Image Contour Extraction Method based on Computer Technology from Li Huanliang, 4^{th} National Conference on Electrical, Electronics and Computer Engineering (NCEECE 2015), 1185-1189 (2016).

According to an embodiment, extracting a geometric characteristic comprises the generation of binary images. Images taken with a multi-beam particle microscope are normally grey-scale images indicating an intensity of detected secondary particle. The data size of such an image is often huge. In contrast thereto, the data size of a binary image just showing for example contours is comparatively small.

According to the disclosure, the distortion correction can be carried out only for parts of the entire image, more precisely for the extracted geometric characteristics of the feature, for example for the extracted contours. This can help make the distortion correction much faster compared to a conventional distortion correction according to known approaches, wherein the distortion correction is carried out for every pixel of a greyscale image. Furthermore, the distortion correction according to the disclosure can involve fewer resources in terms of energy.

The distortion correction as such comprises the steps d) determining a corresponding image subfield comprising the extracted geometric characteristic of the feature; e) determining a position or positions of the extracted geometric characteristic of the feature within the determined corresponding image subfield; and f) correcting the position or positions of the extracted geometric characteristic in the image based on the vector distortion map of the corresponding image subfield, thus creating distortion-corrected image data.

The determination of the corresponding image subfield helps to correct the extracted geometric characteristic with the related image distortion map. The corresponding image subfield can for example be indicated in the meta data of the image or it can be determined based on the position of the data in a memory or in the image data file.

Determining a position or positions of the extracted geometric characteristic of the feature within the determined corresponding image subfield is used because the distortion correction depends on the position or positions.

According to an embodiment, correcting the position or positions of the extracted geometric characteristic in the image based on the vector distortion map of the corresponding image subfield comprises determining a distortion vector for at least one position of the extracted geometric characteristic. If for example a center of a feature (position of a feature) is the geometric characteristic of the feature, the determination of just one distortion vector for this center position can be already sufficient. If the geometric characteristic is for example an edge or a line, this edge or line is described by a plurality of positions and thus a respective plurality of distortion vectors is to be determined for each of the plurality of positions. Analogous considerations hold for geometric characteristics of other shapes.

According to an embodiment, each of the plurality of vector distortion maps is described by a polynomial expansion in vector polynomials. Therefore, it is in general possible to calculate a related distortion vector for an arbitrary position or pixel in the image subfield. Alternatively, each of the plurality of vector distortion maps can be described by 2-dimensional look-up tables. Other representations of the vector distortion “maps” are in general also possible.

A vector polynomial can for example be calculated as follows:

$$( \begin{matrix}d p \\ d q\end{matrix} ) = {\sum }_{i , j , k , l} {A}_{i j k l} ( \begin{matrix}{p}^{i} {q}^{j} \\ {p}^{k} {q}^{l}\end{matrix} ) ,$$

wherein (dp, dq) denotes the distortion vector. According to an example, the sum is calculated for low order terms, only, for example up to the third order. For example, some terms of the sum can be related to a specific kind of correction, such as scale, rotation, shear, keystone, anamorphism.

According to an embodiment, wherein the method steps b) to f) are carried out repeatedly for a plurality of features. It is noted that method step a is not necessarily repeated.

According to an embodiment, other areas in the image do not comprise any features of interest are not distortion-corrected. This significantly reduces the computation effort and saves resources.

According to an embodiment, extracting geometric characteristics of features of interest is carried out for the entire image. In an example, the feature extraction results in a binary image of comparatively small data size. According to a further example, the feature extraction results in a determination of at least a position of a geometric characteristic, for example of a center, a point, an edge, a contour or a line.

According to an embodiment, correcting a position or positions of the extracted geometric characteristic in the image based on the vector distortion map of the corresponding image subfield comprises converting a pixel of the image into at least one pixel of the distortion-corrected image based on the distortion vector. This is due to the fact that a distortion correction does not necessarily result in a positional shift of full pixels. In contrast thereto, it is for example possible that one pixel is shift-distributed over two, three or four pixels (interpolation).

According to an embodiment, correcting position or positions of the extracted geometric characteristic in the image based on the vector distortion of the corresponding image subfield comprises converting a position of the image into at a distortion-corrected position based on a distortion vector polynomial. The vector distortion polynomial is described by a vector polynomial expansion of the vector distortion map of a subfield in the subfield coordinates (p,q), the global coordinates (x,y), or both sets of coordinates.

According to an embodiment, the extracted geometric characteristic of a feature extends over a plurality of image subfields and is thus divided into a respective plurality of parts. In this case, the position or positions of each part of the extracted geometric characteristic is/are individually corrected based on the related individual vector distortion map of the corresponding image subfield of the respective part. Here too, each part of the geometric characteristic can be distortion-corrected with respect to vector distortion map of the image subfield to which the part belongs. This division of features into parts and the respective part-wise distortion correction allows for more precise metrology applications.

According to an embodiment, the method further comprises at least one of the following steps:
determining a dimension of a structure of a semiconductor device in the distortion-corrected image data;
determining an area of a structure of a semiconductor device in the distortion-corrected image data;
determining positions of a plurality of regular objects in a semiconductor device, such as of HAR structures, in the distortion-corrected image data;
determining a line edge roughness in the distortion-corrected image data; and/or determining an overlay error between different features in a semiconductor device in the distortion-corrected image data.

In each case the determination/measurement can be carried out based on the distortion-corrected image data which can, for example, be represented as a set of positional data or as a binary image. This enhances the accuracy of the determination or measurement.

According to an embodiment, the method further comprises the following steps:
providing a test sample with a precisely known and for example repetitive pattern defining a target grid;
imaging the test sample with the multi-beam charged particle microscope, analyzing the obtained image and determining an actual grid based on the analysis;
determining positional deviations between the actual grid and the target grid; and
obtaining the vector distortion map for each image subfield based on the positional deviations.

The above described determination of a vector distortion map or vector distortion field is in general known from imaging calibrated test samples. The accuracy of the obtained vector distortion map strongly depends on the manufacturing accuracy of the pattern on the test sample and on the measurement accuracy when analyzing the test sample.

According to an embodiment, the method further comprises shifting of the test sample from a first position to a second position with respect to the multi-beam charged particle microscope and imaging the test sample in the first position and in the second position. The stage can be moved for shifting, for example of about half an image subfield. The method step can contribute to enhancing the accuracy when high-frequency structures/patterns which are statistically distributed over the sample are imaged.

According to an embodiment, determining positional deviations between the actual grid and the target grid comprises a two-step determination, wherein in a first step a shift of each image subfield, a rotation of each image subfield and a magnification of each subfield are compensated and wherein in a second step the remaining and for example higher order distortions are determined. The latter can be the scanning induced distortions. Therefore, a clear distinction between scanning induced distortions and other distortions can be made.

According to an embodiment, the method further comprises updating the vector distortion maps. Updating can for example be carried out at regular time intervals or on request by a user or whenever a configuration or an operating parameter of the multi-beam charged particle microscope has changed.

According to a second aspect of the disclosure, the disclosure is directed to a method for correcting the distortion in an image that is composed of one or a plurality of image patches, each image patch being composed of a plurality of image subfields, each image subfield being imaged with a related beamlet of a multi-beam charged particle microscope, respectively, the method comprising the following steps:
g) providing a plurality of vector distortion maps for each image subfield, respectively, each vector distortion map characterizing the position dependent distortion for each pixel of the related image subfield;
h) for each pixel in the image: determining a corresponding image subfield comprising the pixel; and
i) for each pixel in the image: converting the pixel in the image into at least one pixel in the distortion-corrected image based on the vector distortion map of the corresponding image subfield.

The definitions of the terms used above are the same as described or defined with respect to the first aspect of the present disclosure. According to the second aspect of the disclosure, the distortion correction can be carried out not only for extracted features, but for the entire distorted image. It can be carried out for example with a PC after imaging with the multi-beam particle microscope.

According to third aspect of the disclosure, the disclosure is directed to a computer program product comprising a program code for carrying out the method as described in any one of the embodiments as described above with respect to the first and second aspect of the disclosure. The program code can be subdivided into one or more partial codes. It is appropriate, for example, to provide the code for controlling the multi-beam particle microscope separately in one program part, while another program part contains the routines for the distortion correction. The distortion correction as such can be carried out on a PC, for example.

According to a fourth aspect of the disclosure, the disclosure is directed to a multi-beam charged particle microscope with a control configured for carrying out the method as described above in various embodiments.

According to a fifth aspect of the disclosure, a correction of the scanning-induced distortion is carried out during image pre-processing. This means that the correction is carried out before the digitized image data is written into an image memory which can be realized as a parallel access memory. For example, an FPGA (“field programmable gate array”) is configured or programmed in such a way that a space dependent distortion correction is carried out for the pixels describing an image subfield. To realize the respective distortion correction, a filter operation is realized by appropriate hardware design/programming that uses a space variant filter kernel that takes the space variant distortion within an image subfield into account, for example by referring to a vector distortion map determined for every image subfield as described above. To take the space variance of the filter kernel into account, a kernel generating unit is applied that calculates the respective filter kernel for each segment of an image subfield individually and optionally “on the fly”. The distortion correction is to be carried out for the data streams of all beamlets in parallel, but it is to be numerically individually adapted to the image subfield/beamlet (imaging channel) in question.

In more detail, the disclosure is directed to a multi-beam charged particle microscope, comprising:
at least a first collective raster scanner for collectively scanning a plurality of J primary charged particle beamlets over a plurality of J image subfields;
a detection unit comprising a detector for detecting a plurality of J secondary electron beamlets, each corresponding to one of the J image subfields; and
a control (800, 820) comprising:
   a scan control unit connected to the first collective raster scanner and configured for controlling during use a raster scanning operation of the plurality of J primary charged beamlets with the first collective raster scanner;
   a kernel generating unit configured for generating during use a space variant filter kernel for space variant distortion correction of the image subfield; and
   an image data acquisition unit, its operation being synchronized with the operation of the detector, the scan control unit and the kernel generating unit, wherein the image data acquisition unit comprises for each of the J image subfields:
      an analogue to digital converter for converting during use an analogue data stream received from the detector into a digital data stream describing the image subfield,
      a hardware filter unit that is configured to receive the digital data stream and that is configured for carrying out during use a convolution of a segment of the image subfield with the space variant filter kernel, thus generating a distortion-corrected data stream, and
      an image memory configured for storing the distortion-corrected data stream as a 2D representation of the image subfield.

The hardware filter unit that is configured to receive the digital data stream and is further configured for carrying out during use a convolution of a segment of the image subfield with the space variant filter kernel, thus generating a distortion-corrected data stream, is implemented within a multi-beam charged particle microscope for the very first time. Since the distortion correction within an image subfield is not constant, but varies within the image subfield, the filter kernel that is used is space variant as well. To take this space dependency into account, the kernel generating unit is applied that allows for calculating/determining the space variant filter kernel for each segment of an image subfield currently filtered within the hardware filter unit.

Furthermore, it is to be taken into account that for the plurality of beamlets a respective plurality of imaging channels exists. Therefore, the distortion correction is to be carried out independently for each imaging channel or in other words for each of the J image subfields individually. Therefore, the image data acquisition unit comprises an analog-to-digital converter, a hardware filter unit and an image memory for each of the imaging channels and therefore for each of the J image subfields.

As already described above, distortion correction carried out in image post-processing is normally realized with a huge cost of computation time, only. However, if the image distortion correction for each image subfield is carried out with a hardware filtering, the computational cost and a desired energy can be significantly reduced. The effect of the hardware filtering as such is a short time delay during data generation before the data stream is stored in an image memory. The kernel generating unit can calculate the space variant filter kernel for the space variant distortion correction of each image subfield “on the fly”, the computational cost of this filter kernel generation being rather moderate.

Of course, the operation of different parts of the multi-beam charged particle microscope can be synchronized, for example by applying clock signals and counting units. The person skilled in the art is aware of possible realizations.

According to an embodiment of the disclosure, the hardware filter unit comprises:
a grid arrangement of filter elements, each filter element comprising a first register temporarily storing a pixel value and a second register temporarily storing a coefficient generated by the kernel generating unit, the pixel values stored in the first register representing a segment of the image subfield;
a plurality of multiplication blocks configured for multiplying pixel values stored in the first registers with the corresponding coefficients stored in the second registers; and
a plurality of summation blocks configured for summing up the results of the multiplications.

As already mentioned above, the hardware filter unit is configured for carrying out during use a convolution of a segment of an image subfield with the space variant filter kernel. Mathematically, a convolution between two matrices can be described as a summation over products calculated from entries within the matrices. Transferred to the present disclosure, the first registers store the entries of a first matrix (pixel values of a segment of an image subfield) and the entries in the second matrix correspond to coefficients generated by the kernel generating unit. In order to carry out the desired multiplications of entries within the two matrices with one another, the plurality of multiplication blocks is provided. Similarly, for the desired summation of the products, the plurality of summation blocks is provided.

The term grid arrangement shall indicate the inner relation/the context of the pixel values and coefficients. A grid arrangement logically corresponds to a matrix representation.

Normally, filtering is a neighboring operation. This means that a filter unit only acts on segments of an image subfield, but not on the entire image subfield. Therefore, according to an embodiment, the hardware filter unit comprises a plurality of shifting registers configured for realizing the grid arrangement of filter elements and for maintaining the order of data in the data stream when passing through the hardware filter unit. These measures can help ensure that the grid arrangement is a realization of a segment of an image subfield and therefore of pixels within an image subfield that are situated in the neighborhood of an image pixel to be distortion-corrected. A shifting register normally has a predetermined size, for example 512 bits or 1024 bits or 2048 or 4096 bits. A shifting register can therefore store a corresponding number of pixels. However, the size of the grid arrangement of filter elements is normally much smaller. Typically, an image segment can for example comprise 11×11 filter elements or 21×21 filter elements or 31×31 filter elements. If a grid arrangement of filter elements has the general size A×A, a plurality of A shifting registers can be applied, wherein the first A entries in the shifting registers belong to the representation of the segment of the image subfield and wherein the remaining entries in the shifting register can be filled with the remaining pixels of a row (or column) of an image subfield. Therefore, basically, the size of the shifting register limits the number of pixels within a row (or column) in an image subfield.

According to an embodiment of the disclosure, a size of the grid arrangement of filter elements is adapted to correct a distortion of at least ten times the pixel size of the image subfield. This means that the size of the grid arrangement of filter elements is generally at least 20×20 or more precisely 21×21 entries. It is noted that the number of filter elements within one row or column is normally chosen to be an odd number since the filter kernel can then be represented in a symmetric way having a unique center. However, mathematically, the size of a grid arrangement of a filter kernel can also be an even number. Furthermore, the pixel size can be the same in different scanning directions, but it can also be different in different scanning directions.

To give an example, a pixel size in an image subfield can be 2 nm. Then, applying a 20×20 or 21×21 filter kernel, a distortion of about 20 nm can be corrected.

In general, the size of the grid arrangement of filter elements determines the maximum distortion that can be corrected, this maximum distortion is approximately half of the size/dimension of the grid arrangement multiplied with the pixel size in the respective dimension or direction.

According to an embodiment, the size of the grid arrangement corresponds to the size of the filter kernel. The number of multiplications that have to be carried out is therefore the number of filter elements. However, the number of multiplications involved then grows quadratically with the number of pixels within a row or column. Therefore, the computational effort increases so does the number of logical units since the hardware filter unit is implemented by hardware. It is therefore an option to reduce the number of logical units. According to an embodiment of the disclosure, a size of the predetermined kernel window is equal to or smaller than the size of a grid arrangement of filter elements. Here, it is to be taken into consideration that the filtering according to the present disclosure is carried out with the purpose of distortion correction. A distortion correction can be understood as a shift of a pixel. This means that even if a full convolution of a full size kernel filter with the pixel values stored in the first register of the filter elements is carried out, there are numerous multiplications that do not have an effect on the result. In other words, shifting a pixel normally results in “distributing” the pixel over four other pixels, for example. The kernel window therefore reflects the part of the filter kernel wherein the entries of the filter kernel have an impact on the result. The other multiplications that could theoretically be carried out in a full convolution do not have any impact and can therefore be omitted. This saves logical units and more precisely this saves multiplication blocks and summation blocks. Of course, it is to be taken into consideration at which position the kernel window is to be placed within the entire filter kernel. Consequently, according to an embodiment of the disclosure, the kernel generating unit is configured to determine during use a position of the kernel window with respect to the grid arrangement of the filter elements.

According to an embodiment, the hardware filter unit further comprises a plurality of switching mechanisms configured for during use logically combining entries and filter elements with multiplication blocks based on the position of the kernel window. Therefore, in order to reduce the number of multiplication blocks and the number of summation blocks, the number of switching mechanisms (for example multiplexers) is be increased. Still, this is easier to implement.

According to an embodiment of the disclosure, the kernel generating unit is configured to determine the space variant filter kernel based on a vector distortion map characterizing the space variant distortion in an image subfield. With respect to the details describing the vector distortion map reference is made to the definitions and explanations given with respect to the first to fourth aspects of the disclosure.

According to an embodiment, the vector distortion map is described by a polynomial expansion in vector polynomials. Alternatively, the vector distortion map is described by a multi-dimensional look-up table.

According to an embodiment, the kernel generating unit is configured to determine the filter kernel based on a function f representatively describing a pixel. In other words, apart from the distortion topic as such, the filter kernel also takes the “shape” of a pixel into consideration. Possible functions for describing a pixel can for example be a Rect2D function describing a rectangular pixel; this corresponds to a linear or bilinear filter. Since a pixel can be blurred in the scanning direction, a possible function f can also be a function Rect (p, q) with different blur in different scanning directions p and q.

Alternatively, the function f describing a pixel can also have the shape of a beam focus of a pixel, for example a Gauss function, an anisotropic function, a cubic function, a sinc function, an airy pattern etc., the filters being truncated at some low-level value. Furthermore, according to an example, the filters should be energy conserving, thus higher order, truncated filter kernels should be normalized to a sum of weights equaling 1. Alternatively, the normalization can be implemented at a later stage and not directly within the filter, the person skilled in the art being aware of advantages and disadvantages of a concrete implementation.

It is noted that pixels at the border of an image subfield will be unusable. However, this effect is well-known from filtering processes in image post-processing. In order to deal with this fact, depending on the size of the filter kernel, a cut-off is used. Still, this does not pose any problem since normally an overlap between neighboring image subfields is realized within multi-beam charged particle microscopes.

According to an embodiment, the image data acquisition unit further comprises counters configured for indicating during use the local coordinates p, q of a pixel within an image subfield that is being filtered. This is relevant for synchronization purposes on the one hand and for determining the individual space dependent scanning induced distortion within an image subfield on the other hand.

According to an embodiment, the image data acquisition unit further comprises an averaging unit implemented in the direction of the data stream after the analog-to-digital converter and before the hardware filter unit. The averaging unit can be applied in order to increase a signal-to-noise ratio. Possible implementations are described within international patent application WO 2021/156198 A1 which is incorporated into the present patent application in its entirety by reference.

According to an embodiment, the image data acquisition unit further comprises a further hardware filter unit configured for carrying out during use a further filter operation, such as low pass filtering, morphologic operations and/or deconvolution with a point-spread function. Of course, it is possible that the image data acquisition unit comprises a plurality of further hardware filter units as well. Here, filtering operations can also be realized by a specifically configured hardware and that it is not necessary to carry out filter operations in image post-processing mandatorily.

According to an embodiment, the hardware filter unit comprises a field programmable gate array (FPGA) or an application-specific integrated circuit (ASIC).

According to an embodiment, the hardware filter unit comprises a sequence of FIFOs. They can realize the shifting registers as explained above in order to realize the grid arrangement of filter elements.

According to an embodiment, the FIFOs are implemented as Block RAMs. According to another embodiment, the FIFOs can be implemented as LUTs (look up tables) or as an externally connected SRAM/DRAM (static or dynamic random access memory). It is noted that there typically exist prefabricated IP blocks from manufacturers of the corresponding chips to instantiate the hardware.

The embodiments of the aspects of the disclosure can be partly or fully combined with one another, as long as no technical contradictions occur.

Of course, other realizations and configurations of the hardware filter unit are also possible.

According to a sixths aspect of the disclosure, the disclosure is directed to a system comprising:
a multi-beam charged particle microscope as described above in numerous embodiments; and
an image postprocessing unit configured for carrying out a distortion correction of image data.

The image postprocessing unit can be provided in addition to the multi-beam charged particle microscope. It can for example comprise an additional PC. However, alternatively, the image postprocessing unit can be included in the multi-beam charged particle microscope. The image postprocessing unit can be configured for carrying out the distortion correction by the image post-processing as described above with respect to the first aspect of the disclosure. Importantly, according to this embodiment of the disclosure, two different kinds of distortion correction can be combined with one another. A first distortion correction can be carried out in image pre-processing (realized as data stream-processing) and a second distortion correction can be carried out afterwards in image post-processing, optionally on extracted geometric characteristics of features of interest, only. Explicit reference is made to the description of the first aspect of the disclosure in this respect.

Similarly, the different aspects of the present disclosure can be combined with one another fully or in part, as long as no technical contradictions occur. Definitions described with respect to one aspect of the disclosure are also valid for other aspects of the disclosure.

According to an example, in a first step, a regularly occurring scanning induced distortion can be corrected according to the second embodiment of the disclosure (wherein a distortion correction is carried out during image preprocessing) and then, in a second step, another or still remaining distortion can be corrected according to the first embodiment of the disclosure (wherein a scanning-induced distortion is corrected during image postprocessing).

### BRIEF DESCRIPTION OF THE DRAWINGS

The disclosure will be even more fully understood by reference to the accompanying drawings, in which:

FIG. 1 is an illustration of a multi-beam charged particle microscope system according to an embodiment;

FIG. 2 is an Illustration of the coordinates of a first inspection site comprising a first and a second image patch and a second inspection site;

FIG. 3 is an Illustration of a static distortion offset of the plurality of primary charged particle beamlets;

FIG. 4A is an Illustration of a scanning deflection at a scanning deflector for an axial beamlet;

FIG. 4B is an Illustration of a scanning deflection at a scanning deflector with scanning induced distortion for an off axis beamlet with propagation angle β;

FIG. 5 is an Illustration of a scanning induced telecentricity aberration for an off axis beamlet with propagation angle β;

FIG. 6 is an Illustration of a typical scanning induced distortion of single beamlet during scanning over an image subfield with image subfield coordinates (p,q);

FIG. 7 is an Illustration of distortion correction in image processing in general;

FIGS. 8A-8C illustrate distortion correction in greyscale images and subsequent feature extraction;

FIGS. 9A-9C illustrate feature extraction and subsequent distortion correction according to the present disclosure;

FIG. 10 is a flowchart of a method for determining a distortion-corrected position of a feature according to the present disclosure;

FIGS. 11A-11B illustrate determination of a vector distortion map based on a target grid;

FIG. 12 is an Illustration of the determination of a distortion vector;

FIGS. 13A-13B illustrate the determination of a grid point;

FIGS. 14A-14B illustrate a dimension measurement based on distortion-corrected image data;

FIGS. 15A-15B illustrate a statistical evaluation of the positions of regular objects based on distortion-corrected image data;

FIG. 16 is an Illustration of an image data acquisition unit and related units or modules;

FIG. 17 is an Illustration of a hardware filter unit;

FIGS. 18A-18B illustrate a convolution of a segment of an image subfield with a filter kernel;

FIG. 19 is an Illustration of an excerpt of filter elements and related elements;

FIG. 20 is an Illustration of a hardware filter unit with a 3×3 filter kernel window; and

FIG. 21 is an Illustration of a hardware filter unit with a 2×2 filter kernel window;

### DETAILED DESCRIPTION

In the exemplary embodiments described below, components similar in function and structure are indicated as far as possible by similar or identical reference numerals.

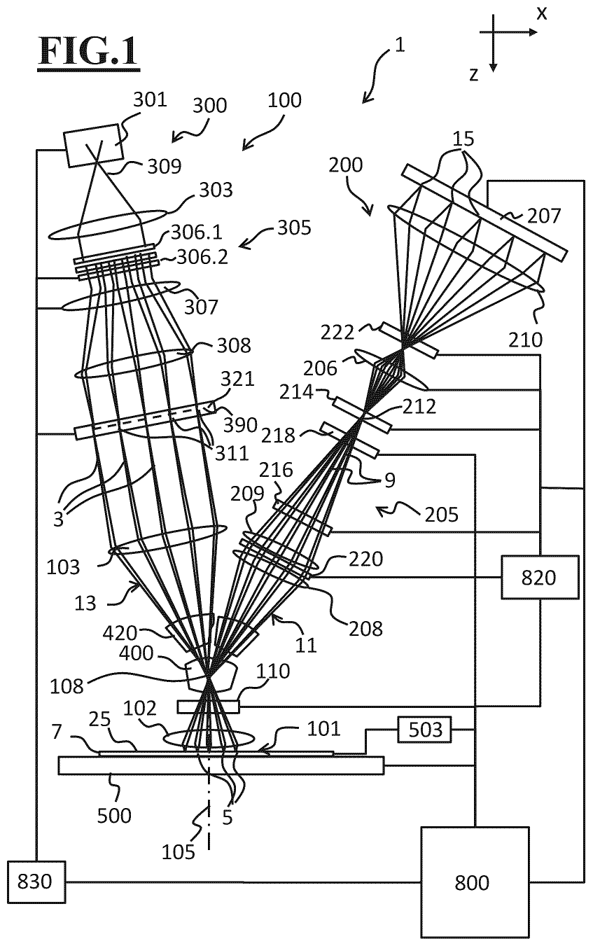

The schematic representation of FIG. 1 illustrates basic features and functions of a multi-beam charged-particle microscopy system 1 according some embodiments of the disclosure. It is to be noted that the symbols used in the figures do not represent physical configurations of the illustrated components but have been chosen to symbolize their respective functionality. The type of system shown is that of a multi-beam scanning electron microscope (MSEM or Multi-SEM) using a plurality of primary electron beamlets 3 for generating a plurality of primary charged particle beam spots 5 on a surface of an object 7, such as a wafer located with a top surface 25 in an object plane 101 of an objective lens 102. For simplicity, only five primary charged particle beamlets 3 and five primary charged particle beam spots 5 are shown. The features and functions of multi-beamlet charged-particle microscopy system 1 can be implemented using electrons or other types of primary charged particles such as ions and for example Helium ions.

The microscopy system 1 comprises an object irradiation unit 100 and a detection unit 200 and a beam splitter unit 400 for separating the secondary charged-particle beam path 11 from the primary charged-particle beam path 13. Object irradiation unit 100 comprises a charged-particle multi-beam generator 300 for generating the plurality of primary charged-particle beamlets 3 and is adapted to focus the plurality of primary charged-particle beamlets 3 in the object plane 101, in which the surface 25 of a wafer 7 is positioned by a sample stage 500.

The primary beam generator 300 produces a plurality of primary charged particle beamlet spots 311 in an intermediate image surface 321, which is typically a spherically curved surface to compensate a field curvature of the object irradiation unit 100. The primary beamlet generator 300 comprises a source 301 of primary charged particles, for example electrons. The primary charged particle source 301 emits a diverging primary charged particle beam 309, which is collimated by at least one collimating lens 303 to form a collimated beam. The collimating lens 303 is usually consisting of one or more electrostatic or magnetic lenses, or by a combination of electrostatic and magnetic lenses. The collimated primary charged particle beam is incident on the primary multi-beam forming unit 305. The multi-beam forming unit 305 basically comprises a first multi-aperture plate 306.1 illuminated by the primary charged particle beam 309. The first multi-aperture plate 306.1 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least further multi-aperture plates 306.2 and 306.3 located, with respect to the direction of movement of the electrons in beam 309, downstream of the first multi-aperture plate 306.1. For example, a second multi-aperture plate 306.2 has the function of a micro lens array and can be set to a defined potential so that a focus position of the plurality of primary beamlets 3 in intermediate image surface 321 is adjusted. A third, active multi-aperture plate arrangement 306.3 (not illustrated) comprises individual electrostatic elements for each of the plurality of apertures to influence each of the plurality of beamlets individually. The active multi-aperture plate arrangement 306.3 consists of one or more multi-aperture plates with electrostatic elements such as circular electrodes for micro lenses, multi-pole electrodes or sequences of multipole electrodes to form static deflector arrays, micro lens arrays or stigmator arrays. The multi-beamlet forming unit 305 is configured with an adjacent first electrostatic field lenses 307, and together with a second field lens 308 and the second multi-aperture plate 306.2, the plurality of primary charged particle beamlets 3 is focused in or in proximity of the intermediate image surface 321.

In or in proximity of the intermediate image plane 321, a static beam steering multi aperture plate 390 is arranged with a plurality of apertures with electrostatic elements, for example deflectors, to manipulate individually each of the plurality of charged particle beamlets 3. The apertures of the beam steering multi aperture plate 390 are configured with larger diameter to allow the passage of the plurality of primary charged particle beamlets 3 even in case the focus spots of the primary charged particle beamlets 3 deviate from the intermediate image plane or their lateral design position. In an example, the beam steering multi aperture plate 390 can also be formed as a single multi-aperture element.

The plurality of focus points of primary charged particle beamlets 3 passing the intermediate image surface 321 is imaged by field lens group 103 and objective lens 102 in the image plane 101, in which the investigated surface 25 of the object 7 is positioned. The object irradiation system 100 further comprises a collective multi-beam raster scanner 110 in proximity to a first beam cross over 108 by which the plurality of charged-particle beamlets 3 can be deflected in a direction perpendicular to the direction of the beam propagation direction or the optical axis 105 of the objective lens 102. In the example of FIG. 1, the optical axis 105 is parallel to the z-direction. Objective lens 102 and collective multi-beam raster scanner 110 are centered at the optical axis 105 of the multi-beamlet charged-particle microscopy system 1, which is perpendicular to wafer surface 25. The wafer surface 25 arranged in the image plane 101 is then raster scanned with collective multi-beam raster scanner 110. Thereby the plurality of primary charged particle beamlets 3, forming the plurality of beam spots 5 arranged in a raster configuration, is scanned synchronously over the wafer surface 101. In an example, the raster configuration of the focus spots 5 of the plurality of primary charged particle beamlets 3 is a hexagonal raster of about hundred or more primary charged particle beamlets 3. The primary beam spots 5 have a distance about 6 μm to 15 μm and a diameter of below 5 nm, for example 3 nm, 2 nm or even below. In an example, the beam spot size is about 2 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets generated at each beam spot 5 depends on the intensity of the impinging primary charged particle beamlet 3, illuminating the corresponding spot, and the material composition and topography of the object 7 under the beam spot 5. Secondary charged particle beamlets 9 are accelerated by an electrostatic field generated by a sample charging unit 503, and collected by objective lens 102, directed by beam splitter 400 to the detection unit 200. Detection unit 200 images the secondary electron beamlets 9 onto the image sensor 207 to form there a plurality of secondary charged particle image spots 15. The detector comprises a plurality of detector pixels or individual detectors. For each of the plurality of secondary charged particle beam spots 15, the intensity is detected separately, and the material composition of the wafer surface 25 is detected with high resolution for a large image patch with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. For example, the image patch is sampled with half of the beam spot size, thus with a pixel number of 8000 pixels per image line for each beamlet, such that the digital data set representing the image patch generated by 100 beamlets comprises 6.4 gigapixel. The image data is collected by control unit 800. Details of the image data collection and processing, using for example parallel processing, are described in German patent application 102019000470.1 and in U.S. Pat. No. 9,536,702, which are hereby incorporated by reference.

The plurality of secondary electron beamlets 9 passes the first collective multi-beam raster scanner 110 and is scanning deflected by the first collective multi-beam raster scanner 110 and guided by beam splitter unit 400 to follow the secondary beam path 11 of the detection unit 200. The plurality of secondary electron beamlets 9 are travelling in opposite direction from the primary charged particle beamlets 3, and the beam splitter unit 400 is configured to separate the secondary beam path 11 from the primary beam path 13 usually using magnetic fields or a combination of magnetic and electrostatic fields. Optionally, additional magnetic correction elements 420 are present in the primary or in the secondary beam paths. Projection system 205 further comprises at least a second collective raster scanner 222, which is connected to projection system control unit 820 or more generally to an imaging control module 820. Control unit 800 is configured to compensate a residual difference in position of the plurality of focus points 15 of the plurality of secondary electron beamlets 9, such that the position of the plurality secondary electron focus spots 15 are kept constant at image sensor 207.

The projection system 205 of detection unit 200 comprises further electrostatic or magnetic lenses 208, 209, 210 and a second cross over 212 of the plurality of secondary electron beamlets 9, in which an aperture 214 is located. In an example, the aperture 214 further comprises a detector (not shown), which is connected to projection system control unit 820. Projection system control unit 820 is further connected to at least one electrostatic lens 206 and a third deflection unit 218. The projection system 205 further comprises at least a first multi-aperture corrector 220, with apertures and electrodes for individual influencing each of the plurality of secondary electron beamlets 9, and an optional further active element 216, for example a multi-pol element connected to control unit 800.

The image sensor 207 is configured by an array of sensing areas in a pattern compatible to the raster arrangement of the secondary electron beamlets 9 focused by the projecting lens 205 onto the image sensor 207. This enables a detection of each individual secondary electron beamlet 9 independent of the other secondary electron beamlets 9 incident on the image sensor 207. A plurality of electrical signals is created and converted in digital image data and processed to control unit 800. During an image scan, the control unit 800 is configured to trigger the image sensor 207 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The image sensor 207 illustrated in FIG. 1 can be an electron sensitive detector array such as a CMOS or a CCD sensor. Such an electron sensitive detector array can comprise an electron to photon conversion unit, such as a scintillator element or an array of scintillator elements. In an example, the image sensor 207 can be configured as electron to photon conversion unit or scintillator plate arranged in the focal plane of the plurality of secondary electron particle image spots 15. In this example, the image sensor 207 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above. In an example, the relay optical system further comprises a beam splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets 9 according the scanning speed of the plurality of primary charged particle beamlets 3. The first, slow light detector can be a CMOS or CCD sensor, providing a high-resolution sensor data signal for monitoring the focus spots 15 or the plurality of secondary electron beamlets 9 and for control of the operation of the multi-beam charged particle microscope.

In the example, the primary charged particle source is implemented in form of an electron source 301 featuring an emitter tip and an extraction electrode. When using primary charged particles other than electrons, for example helium ions, the configuration of the primary charged-particle source 301 may be different to that shown. Primary charged-particle source 301 and active multi-aperture plate arrangement 306.1 . . . 306.3 and beam steering multi aperture plate 390 are controlled by primary beamlet control module 830, which is connected to control unit 800.

During an acquisition of an image patch by scanning the plurality of primary charged particle beamlets 3, the stage 500 is generally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by certain known sensors, such as laser interferometers, grating interferometers, confocal micro lens arrays, or similar.

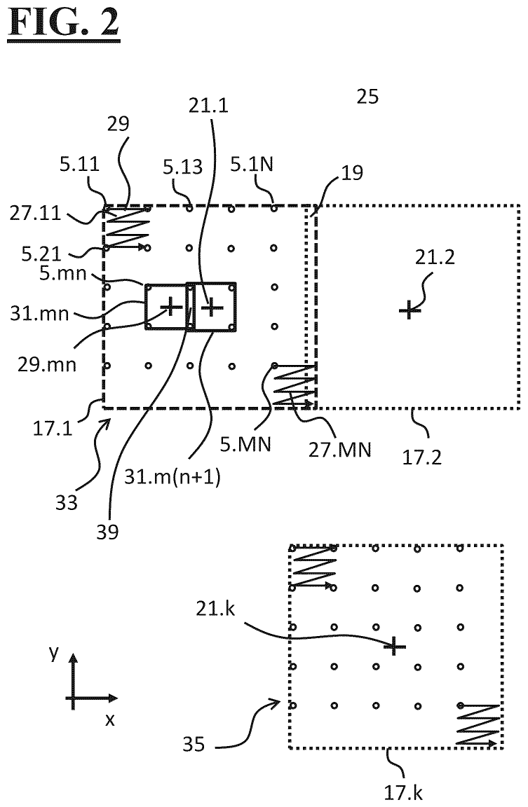

The method of wafer inspection by acquisition of image patches is explained in more detail in FIG. 2. The wafer is placed with its wafer surface 25 in the focus plane of the plurality of primary charged particle beamlets 3, with the center 21.1 of a first image patch 17.1. The predefined position of the image patches 17.1 . . . k corresponds to inspection sites of the wafer for inspection of semiconductor features. The application is not limited to wafer surfaces 25, but is for example also applicable for lithography masks used for semiconductor fabrication. The word “wafer” shall thus not be limited to semiconductor wafers, but include general objects used for or fabricated during semiconductor fabrication.

The predefined positions of the first inspection site 33 and second inspection site 35 are loaded from an inspection file in a standard file format. The predefined first inspection site 33 is divided into several image patches, for example a first image patch 17.1 and a second image patch 17.2, and the first center position 21.1 of the first image patch 17.1 is aligned under the optical axis 105 of the multi-beam charged-particle microscopy system 1 for the first image acquisition step of the inspection task. The first center of a first image patch 21.1 is selected as the origin of a first local wafer coordinate system for acquisition of the first image patch 17.1. Methods to align the wafer 7, such that the wafer surface 25 is registered and a local coordinate system of wafer coordinates is generated, are well known.

The plurality of primary beamlets 3 is distributed in a mostly regular raster configuration in each image patch 17.1 . . . k and is scanned by a raster scanning mechanism to generate a digital image of the image patch. In this example, the plurality of primary charged particle beamlets 3 is arranged in a rectangular raster configuration with N primary beam spots 5.11, 5.12 to 5.1N in the first line with N beam spots, and M lines with beam spots 5.11 to beam spot 5.MN. Only M=five times N=five beam spots are illustrated for simplicity, but the number of beam spots J=M times N can be larger, for example J=61 beamlets, or about 100 beamlets or more, and the plurality of beam spots 5.11 to 5.MN can have different raster configurations such as a hexagonal or a circular raster.

Each of the primary charged particle beamlet is scanned over the wafer surface 25, as illustrated at the example of primary charged particle beamlet with beam spot 5.11 and 5.MN with scan path 27.11 and scan path 27.MN. Scanning of each of the plurality of primary charged particles is performed for example in a back- and forth movement with scan paths 27.11 . . . 27.MN, and each focus point 5.11 . . . 5.MN of each primary charged particle beamlet is moved by the multi-beam scanning deflector system 110 collectively in x-direction from a start position of an image subfield line, which is in the example the most left image point of for example image subfield 31.mn. Each focus point 5.11 . . . 5.MN is then collectively scanned by scanning the primary charged particle beamlets 3 collectively to the right position, and then the collective multi-beam raster scanner 110 moves each of the plurality of charged particle beamlets in parallel to line start positions of the next lines in each respective subfield 31.11 . . . 31.MN. The movement back to line start position of a subsequent scanning line is called flyback. The plurality of primary charged particle beamlets 3 follows in mostly parallel scan paths 27.11 to 27.MN, and thereby a plurality of scanned images of the respective subfields 31.11 to 31.MN is obtained in parallel. For the image acquisition, as described above, a plurality of secondary electrons is emitted at the focus points 5.11 to 5.MN, and a plurality of secondary electron beamlets 9 is generated. The plurality of secondary electron beamlets 9 are collected by the objective lens 102, pass the first collective multi-beam raster scanner 110 and are guided to the detection unit 200 and detected by image sensor 207. A sequential stream of data of each of the plurality of secondary electron beamlets 9 is transformed synchronously with the scanning paths 27.11 . . . 27.MN in a plurality of 2D datasets, forming the digital image data of each image subfield. The plurality of digital images of the plurality of image subfields is finally stitched together by an image stitching unit to form the digital image of the first image patch 17.1. Each image subfield is configured with small overlap area with adjacent image subfield, as illustrated by overlap area 39 of subfield 31.mn and subfield 31.m (n+1).

Next, the desired properties or specifications of a wafer inspection task are illustrated. For a high throughput wafer inspection, the time for image acquisition of each image patch 17.1 . . . k including the time used for image postprocessing is fast. On the other hand, tight specifications of image qualities such as the image resolution, image accuracy and repeatability is maintained. For example, the desire for image resolution is typically 2 nm or below, and with high repeatability. Image accuracy is also called image fidelity. For example, the edge position of features, in general the absolute position accuracy of features is to be determined with high absolute precision. Typically, the desire for the position accuracy is about 50% of the desired resolution or even less. For example, measurement tasks involve an absolute precision of the dimension of semiconductor features with an accuracy below 1 nm, below 0.3 nm or even 0.1 nm. Therefore, a lateral position accuracy of each of the focus spots 5 of the plurality of primary charged particle beamlets 3 is below 1 nm, for example below 0.3 nm or even below 0.1 nm. Under high image repeatability it is understood that under repeated image acquisition of the same area, a first and a second, repeated digital image are generated, and that the difference between the first and second, repeated digital image is below a predetermined threshold. For example, the difference in image distortion between first and second, repeated digital image is below 1 nm, for example 0.3 nm, such as below 0.1 nm, and the image contrast difference is below 10%. In this way a similar image result is obtained even by repetition of imaging operations. This is important for example for an image acquisition and comparison of similar semiconductor structures in different wafer dies or for comparison of obtained images to representative images obtained from an image simulation from CAD data or from a database or reference images.

One of the desired properties or specifications of a wafer inspection task is throughput. The measured area per acquisition time is determined by the dwell time, the pixel size and the number of beamlets. Typical examples of dwell times are between 2 ns and 800 ns. The pixel rate at the fast image sensor 207 is therefore in a range between 1.25 Mhz and 500 MHz and each minute, about 15 to 20 image patches or frames could be obtained. For 100 beamlets, typical examples of throughput in a high-resolution mode with a pixel size of 0.5 nm is about 0.045 sqmm/min (square-millimeter per minute), and with larger number of beamlets, for example 10000 beamlets and 25 ns dwell time, a throughput of more than 7 sqmm/min is possible. However, in certain known systems the desired properties for digital image processing limits the throughput significantly. For example, a digital compensation of a scanning distortion according to certain known methods is very time consuming and therefore unwanted.

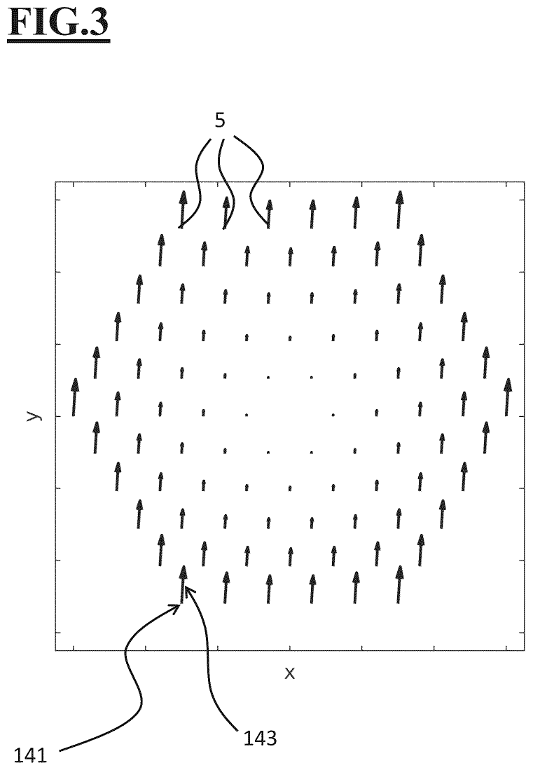

The imaging performance of a charged particle microscope 1 is limited by design and higher order aberrations of the electrostatic or magnetic elements of the object irradiation unit 100, as well as fabrication tolerances of for example the primary multi-beamlet-forming unit 305. The imaging performance is limited by aberrations such as for example distortion, focus aberration, telecentricity and astigmatism of the plurality of charged particle beamlets. FIG. 3 illustrates as an example a typical static distortion aberration of a plurality of primary charged particle beamlets 3 in the image plane 101. The plurality of primary charged particle beamlets 3 is focused in the image plane to form a plurality of primary charged particle beam spots 5 (three are indicated) in a raster configuration, in this example in a hexagonal raster. In an ideal system, with the collective multi-beam raster scanner 110 switched off, each of the beam spots 5 is formed at the center position 29.mn (see FIG. 2) of a corresponding image subfield 31.mn (with index m for the line number and n for the column number). In a real system, however, the beam spots 5 are formed at slightly deviating positions, which deviate from the ideal positions on the ideal raster such as illustrated by the static distortion vectors in FIG. 3. For the illustrated example of the primary beam spot 141, the deviation from the ideal position on the hexagonal raster is described by distortion vector 143. The distortion vectors give the lateral differences [dx, dy] from the ideal positions and the maximum absolute value of distortion vectors can be in range of several nm, for example above 1 nm, 2 nm or even above 5 nm. Typically, the static distortion vectors of a real system are measured and compensated by an array of static deflection elements such as any of the active multi-aperture plate arrangements 306.2. In addition, drifts or a dynamic change of the static distortion is considered and compensated, as described in German patent application No. 102020206739.2, filed on May 28, 2020, which is incorporated by reference. The control and compensation of aberrations is achieved by a monitoring or detection system and a control loop capable of driving compensators for example several times during an image scan, such that aberrations of the multi-beam charged particle microscope 1 are compensated.

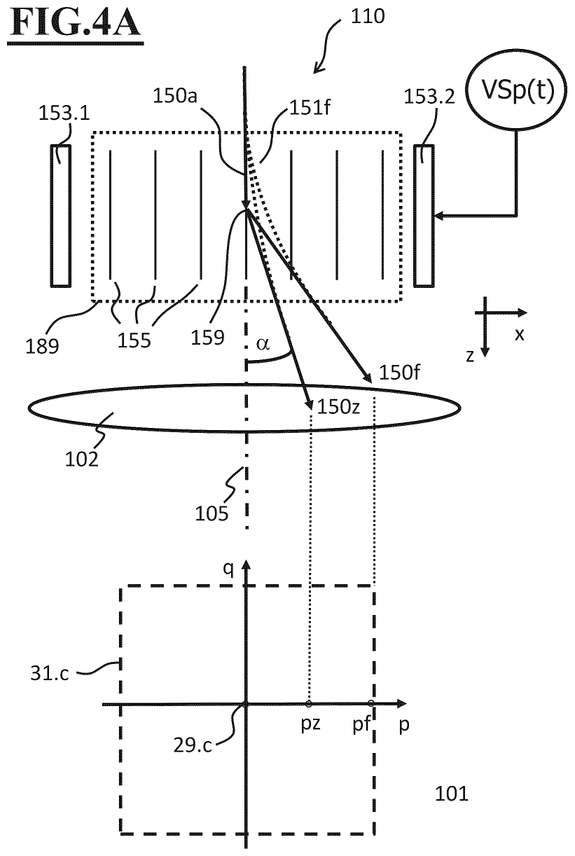

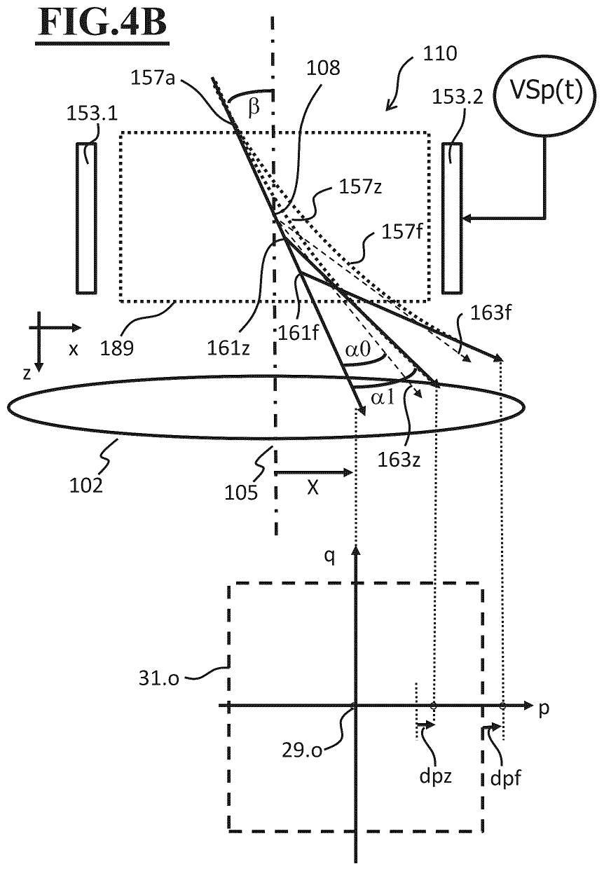

However, the imaging performance of a charged particle microscope is not only limited by the design aberrations and drift aberrations of the electrostatic or magnetic elements of the object irradiation unit 100, but for example also by the first collective multi-beam raster scanner 110. Deflection scanning systems and their properties have been investigated in great depth for single beam microscopes. However, for multi-beam microscopes, conventional deflection scanning system for scanning deflection of a plurality of charged particle beamlets exhibits an intrinsic property. The intrinsic property is illustrated at the beam path through a deflection scanner in FIGS. 4A-4B in more detail.

FIG. 4A illustrates a beam path of a single primary charged particle beam through a scanning deflector 110 of the prior art with deflector electrodes 153.1 and 153.2 and a voltage supply. For sake of simplicity, only the deflection scanner electrodes for raster scanning deflection in the first direction are illustrated. During use, a scanning deflection voltage difference VSp(t) is applied and an electrostatic field is formed with equipotential lines 155 between the electrodes 153.1 and 153.2. An axial charged particle beamlet 150a, corresponding to an image patch 31.c with image patch center 29.c coincident with the optical axis 105, is deflected by the electrostatic field and passes the intersection volume 189 between the deflector electrodes 153.1 and 153.2 along real beam path 151f. The beam trajectory can be approximated by first order beam-paths 150a and 150f with a single virtual deflection at pivot point 159. The charge particle beamlet travelling along path 150z is focused by objective lens 102 in the object plane 101, illustrated in the lower part of FIG. 4A. The subfield coordinates are given in relative coordinates (p,q) relative to the center point 29.c of the subfield 31.c.

For a maximum deflection to a maximum subfield point at coordinate p_{f}, a maximum voltage difference of VSpₘₐₓ is applied, and for deflection of the incident beamlet 150a to a subfield point at distance p_{z}, a corresponding voltage VSp is applied, and the incident beamlet 150a is deflected by deflection angle α in direction of beam path 150z. Nonlinearities of the deflector are compensated by determining the functional dependency of the deflection angle α and the deflector voltage difference VSp. By calibration of the functional dependency VSp(sin(α)), an almost ideal scanner for a single primary charged particle beamlet is achieved, with a single common pivot point 159 for deflection scanning of a single charged particle beamlet. It is noted that the lateral displacement (p,q) of a beam spot position in the image plane is proportional to the focal length f of the objective lens 102 multiplied by the sin(α). For example of the zonal field point, p_{z}=f sin(α_{z}). For small angles α, the function sin(α) is typically approximated by α. As will be described in more detail below, despite the fact that a scanning induced distortion can be minimized for a single beam microscope, nevertheless other scanning induced aberrations such as astigmatism, defocus, coma or spherical aberration can deteriorate the resolution of a charged particle microscope with increasing field size. In addition, with increasing field size, a deviation from the virtual pivot point 159 becomes more and more significant.

In a multi-beam system, a plurality of charged particle beamlets is scanned in parallel with the same deflection scanner and the same voltage differences according the functional dependency VSp(sin(α)). In FIG. 4B, the cross over 108 of the plurality of primary charged particle beamlets is coincident with the virtual pivot point 159 of the axial primary beamlet 150a, and each of the charged particle beamlets pass the electrostatic field at different angles. A charged particle beamlet 157a with angle of incidence of β is illustrated, with corresponding subfield 31.0 with center of image subfield 29.0. The angle β is related to the distance X of the center coordinate 29.0 to the optical axis 105 by sin(B)=X/f, with the focal length f of the objective lens 102. With deflection scanner 110 switched off (VSp(t)=0V), the beamlet traverses the path 157a and is focused by objective lens 102 to the center point 29.0 of the subfield 31.0. However, if a voltage difference is applied, despite the fact that the deflection scanner is approximately ideal for an axial beamlet as illustrated in FIG. 4A, it is not ideal for a field beamlet under angle of incidence β. Due to the finite thickness of the deflection field, the path lengths through the electrostatic field are different for each incident beamlet of different angle of incidence β, and the real beam-paths 157z and 157f deviate from ideal beam-paths of first order 163z and 163f. This is illustrated for beam-paths for the two subfield points with coordinates p_{z} and p_{f} with real beam-paths 157z and 157f. The angles of the real beam-paths 157z and 157f deviate from the angles of the ideal beam paths 163z and 163f, and each beam is virtually deflected at a different virtual pivot point 161z and 161f deviating from the beam cross over 108. For example, if voltage VSp(sin(α₀)) is applied, the primary charged particle beamlet 157a is deflected by angle α1 instead of angle α0 and follows beam-path 157z with a virtual deflection point 161z. The charge particle beam spot is therefore distorted by local distortion vector dpz.

The deviation of deflection angles increases with increasing angle of incidence β, and an increasing scanning induced distortion is generated by the collective multi-beam raster scanner 110.

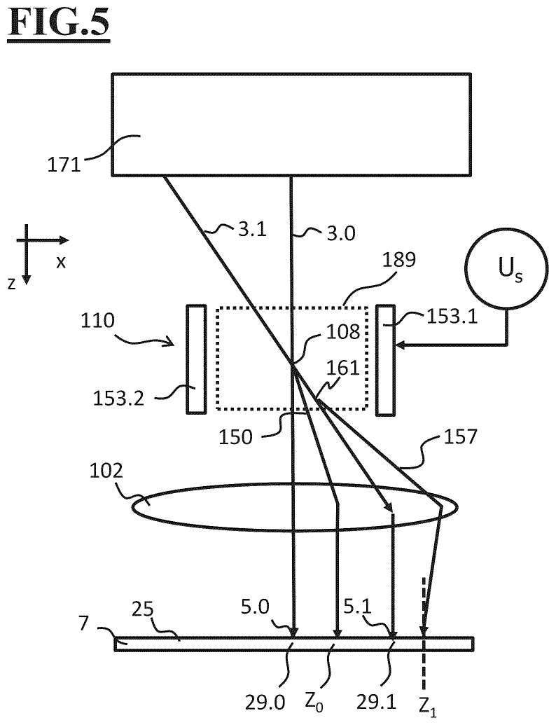

The differences of the deflection angles α generate a scanning induced distortion, the differences in the position of the virtual pivot point are the cause for scanning induced telecentricity aberrations. FIG. 5 illustrates simplified the system 171 in front of the scanning collective multi-beam raster scanner 110, from which a plurality of primary charged particles is incident on the first collective multi-beam raster scanner 110. The plurality of charged particle beamlets is illustrated by two beamlets including an axial charged particle beamlet 3.0 and an off axis beamlet 3.1, which pass the intersection volume 189 of the raster scanner 110 and are focused by objective lens 102 to form a plurality of focus points, illustrated by focus points 5.0 and 5.1 on a surface 25 of a wafer 7. When the raster scanner 110 is in an off state and no voltage difference VSp is applied to the electrodes 153, the beam spots 5.0 and 5.1 are at the center points 29.0 and 29.1 of the respective image subfields. If a voltage difference VSp(sin(α₀)) is applied, the beamlet 3.0 follows the ideal path 150 and is deflected to zonal field point Z₀. In the linear representation of FIG. 5, beamlet 3.0 appears to be deflected at the beam cross over 108 corresponding to the virtual pivot point 159 of FIG. 4A. Therefore, beamlet 3.0 illuminates the wafer surface 25 at the same angle of incidence as at center position 29.0. The off axis beamlet 3.1 is deflected to the corresponding zonal field point Z₁ of the corresponding image subfield. Off axis beamlet 3.1 appears to be deflected along representative beam-path 157 at virtual deflection point 161, deviating from the beam cross over 108. Therefore, the telecentricity angle of the beamlet 3.1 at scanning position for the zonal field point Z₁ deviates from the telecentricity angle at the central field 29.1, corresponding to a scanning induced telecentricity aberration for beamlet 3.1 in addition to the distortion described above. In a third embodiment of the disclosure, scanning induced telecentricity aberration is reduced by a second multibeam scanning correction system 602.

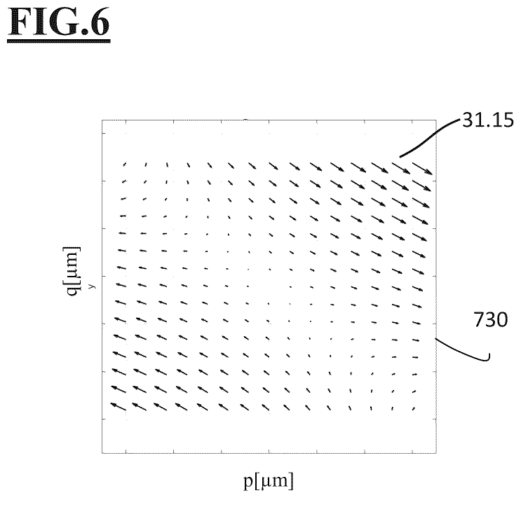

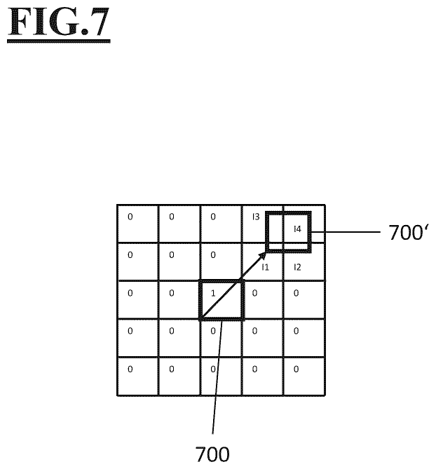

The deviation of the focus positions at the scan positions of each of the plurality of charged particle beamlets 3 is described by a scanning distortion vector field (also referred to as a vector distortion map) for each image subfield 31.11 to 31.MN. FIG. 6 illustrates the scanning distortion at the example of the image subfield 31.15 (see FIG. 7). Throughout the disclosure, the image subfield coordinates (p,q) relative to the respective center of each image subfield 31.mn are used, and the scanning distortion is described by vector [dp,dq] as a function of image subfield coordinates (p,q) for each individual image subfield 31.mn. The center position (p,q)=(0,0) of each image subfield is described in (x,y)-coordinates with respect to the optical axis 105. Each image center coordinate can be distorted from a predetermined ideal raster configuration by a static offset (dx,dy) as a function of (x,y)-coordinates, as illustrated in FIG. 3. The static distortion is typically compensated by static multi aperture plate 306.2, and not considered in the scanning distortion [dp,dq]. Since the scanning distortion is different in each image subfield 31.11 . . . 31.MN, the scanning distortion is generally described by a scanning distortion vector [dp,dq]=[dp,dq] (p,q;xᵢⱼ,yᵢⱼ) depending on four coordinates. The four coordinates are formed by the local image subfield coordinates (p,q) and the discrete center coordinates of image subfields (xᵢⱼ, yᵢⱼ).

FIG. 6 shows the scanning distortion vectors [dp,dq] over the image subfield 31.15. In this example, the maximum scanning distortion is at the maximum image subfield coordinate p=q=6 μm with the scanning distortion vector [dp,dq]=[2.7 nm, −1.6 nm]. The length of the maximum scanning distortion vector in this image subfield is 3.5 nm. Typical maximum scanning distortion aberrations in the image subfields are in the range of 1 nm to 4 nm, but may even exceed 5 nm.

FIG. 7 is an illustration of distortion correction in image processing in general. Image distortion correction as such is well-known. Then, image distortion correction is carried out in image post processing. Correcting a distortion can be described as a displacement of a pixel with a position dependent displacement vector, since the distortion varies from pixel to pixel. The position dependent displacement vector can be mathematically described by the result of a matrix-vector multiplication. Furthermore, it is to be taken into account that a distortion is normally not given in terms of full pixels. In other words, in addition to the mere displacement an interpolation of pixel values is to be carried out. These facts are schematically shown in FIG. 7: A pixel 700 is displaced because of distortion and the resulting pixel position is indicated with a reference sign 700′. The value of the pixel 700 has been set to 1. Due to the displacement, the value or intensity 1 is to be distributed over four pixels in the distortion-corrected image: The respective pixels have the intensities/values I1, I2, I3 and I4.

If a complete image is distortion-corrected using image processing, this is numerically expensive: For each original pixel in the distorted image, a multiplication with an n×m matrix is to be carried out, and additionally an interpolation is to be carried out. To give an example, the image of a multi-beam charged particle microscope comprises 10 Gigapixel. Therefore, distortion correction involves four operations per pixel plus the interpolation so that at least 40 Billion operations are involved which is a huge amount.

However, in metrology, what really counts is the exact position of an image detail. According to the disclosure, the positions of the image details are determined in the original, still distorted image and afterwards these positions are distortion corrected. If for example it is the aim to determine the positions of HAR-structures (high-aspect ratio structures) in a semiconductor sample, the numerical expense can be reduced by a factor of about 100000 (assuming that a 100×100 μm² image field comprises 10 Gigapixel and that HAR-structures have an approximate diameter of about 100 nanometer and a pitch of about 300 nanometer).

According to the disclosure, the distortion in terms of a vector distortion map 730 is determined for each image subfield 31.mn, since the distortion is different for each image subfield 31.mn and varies within each image subfield 31.mn. Generating a vector distortion map is known per se. The distortion in each image subfield 31.mn can for example be described by a polynomial expansion in vector polynomials. This is in general known, for example from the measurement of calibrated objects. Additionally, an object or test sample can be displaced between a first and second measurement, and the distortion can be determined based on the difference between the two measurements. These measurements can also be carried out repeatedly. Therefore, it is possible to determine a distortion. The distortion and more precisely the vector distortion map 730 and/or its representation as a polynomial expansion in vector polynomials can be stored in a memory for each image subfield. It can also be updated in predetermined time intervals.

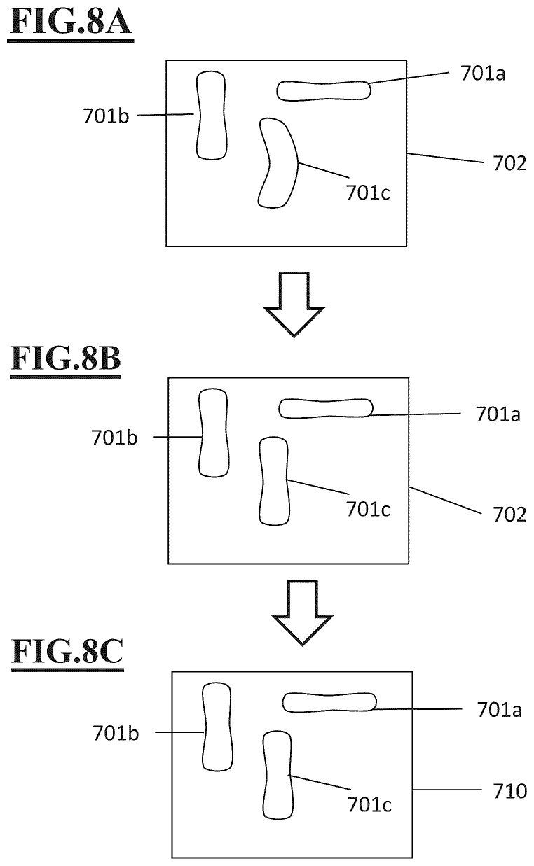

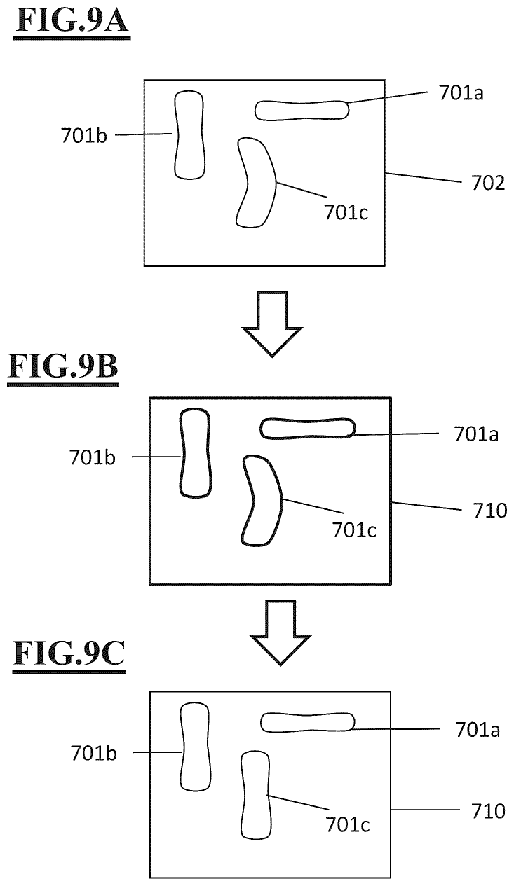

FIGS. 8 and 9 illustrate the distortion correction according to conventional image processing on the one hand (FIGS. 8A-8C) and according to the present disclosure on the other hand (FIG. 9). In more detail, FIG. 8A depicts a grayscale image 702. The grayscale image 702 can in general be a complete image, just an image patch or even just an image subfield—this does not make a difference when explaining the idea. The grayscale image 702 comprises three features of interest 701a, 701b and 701c. In general, these features 701a, 701b and 701c can be distorted, wherein the distortion is illustratively shown for the feature 701c which is curved. The original grayscale image 702 is distortion-corrected according to known approaches wherein the distortion correction is carried out for every pixel of the grayscale image. The result is depicted in FIG. 8B: The feature 701c is no longer distorted, feature 701c is no longer curved. In a next step, the contours of the features 701a, 701b and 701c are extracted from the grayscale image 702 and the binary image 710 is generated which is depicted in FIG. 8C. Based on the contours in the binary image 710, it is possible to carry out precision measurements or metrology applications. It is noted that for purposes of illustration and distinction, a grayscale image 702 comprises a dotted background and a binary image 710 comprises a white background.

Turning now to FIGS. 9A-9C illustrating the correction process according to the present disclosure, the original situation depicted in FIG. 9A is the same. However, then, first, all features of interest are identified and extracted. FIG. 9B illustrates a binary image 710 comprising only the contours of the features 701a, 701b and 701c. These contours are still distorted. However, the amount of data in the binary image is significantly reduced compared to the grayscale image according to known approaches. Then, in the next step, the contours of the features 701a, 701b and 701c are distortion-corrected. Here, due to the nature of the distortion which is a scanning induced distortion, the distortion correction is carried out for each image subfield individually, and the distortion correction of each pixel in each image subfield 31.mn is position dependent.

For reasons of illustration, FIGS. 9A-9C show a simplified approach of the improved correction of scanning induced distortion. According to a further example of the method for correcting scanning induced distortion, at least a position of features of interest 701a, 701b, 701c is extracted from the uncorrected digital image and a distortion correction is applied to only the positions of the features of interest 701a, 701b, 701c by for example a polynomial expansion of the vector distortion maps. Therefore, a distortion correction is not limited to the pixel raster of the digital image.

Therefore, more generally, the illustration shown in FIG. 9B can alternatively be interpreted as a visualization of connected line segments consisting of a set of non-integer positions or non-integer coordinates of the features of interest 701a, 701b, 701c obtained by feature extraction from the grayscale image 702. Similarly, FIG. 9C can be interpreted as a visualization of connected line segments of non-integer positions or non-integer coordinates of the distortion-corrected features of interest 701a, 701b, 701c.

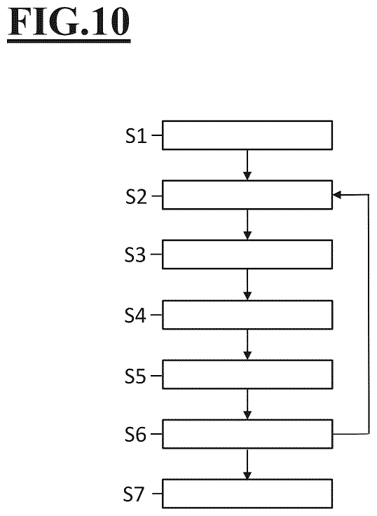

FIG. 10 illustrates a flowchart of a method for determining a distortion-corrected position of a feature 701 in an image that is composed of one or a plurality of image patches, each image patch being composed of a plurality of image subfields 31.mn, each image subfield 31.mn being imaged with a related beamlet of a multi-beam charged particle microscope, respectively. In a first method step S1, a plurality of vector distortion maps 730 is provided for each image subfield 31.mn, respectively. Each vector distortion map 730 characterizes the position dependent distortion for each pixel of the related image subfield 31.mn. Furthermore, as already explained in the general part of the present application, the term “map” has to be interpreted broadly. It shall indicate that for each image subfield 31.mn a vector field with distortion vectors is provided. It is for example possible that each of the plurality of vector distortion maps 730 is described by a polynomial expansion in vector polynomials. The concrete distortion for a position p,q in the image subfield 31.mn can then be calculated from the polynomial expansion. Alternatively, each of the plurality of vector distortion maps 730 can be described by 2-dimensional look-up tables. Other representations are in general also possible.

In method step S2 a feature of interest 701 is identified in the image. In method step S3 a geometric characteristic of the feature 701 is extracted. It is possible to carried out method steps S2 and S3 separately, but they can also be combined with one another. In general, a geometric characteristic of a feature of interest 701 can be of any type or any shape. A geometric characteristic of the feature 701 can for example be the contour of the feature 701. It can alternatively be just parts of the contour, for example an edge or a corner. It can also be a center of the feature of interest 701. Examples for the geometric characteristic of the feature 701 can be at least one of the following: a contour, an edge, a corner, a point, a line, a circle, an ellipse, a center, a diameter, a radius, a distance. Other geometric characteristics as well as irregular forms are also possible. Geometric characteristics can also comprise a property, such as a line edge roughness, an angle between two lines or the like or an area or a volume.

In the next step S4 a corresponding image subfield 31.mn comprising the extracted geometric characteristic of the feature 701 is determined. In step S5 a position or positions of the extracted geometric characteristic of the feature 701 within the determined corresponding image subfield 31.mn is or are determined. Whether just one position or a plurality of positions is determined depends on the nature of the extracted geometric characteristic. Having determined the corresponding image subfield 31.mn and having determined the position or positions of pixels in the respective image subfield 31.mn allows for unambiguously assigning a distortion vector 715 (or a plurality of distortion vectors 715) for the correction carried out in method step S6: According to method step S6 the position or positions of the extracted geometric characteristic in the image are corrected based on the vector distortion map 730 of the corresponding image subfield 31.mn, thus creating distortion-corrected image data. It is possible that the method steps S2 to S6 are carried out repeatedly for a plurality of features 701.

Afterwards, in method S7, the procedure can end or one or more metrology applications or measurements can be carried out: Examples are the determination of a dimension of a structure of a semiconductor device in the distortion-corrected image, the determination of an area of a structure of a semiconductor device in the distortion-corrected image; the determination of positions of a plurality of regular objects in a semiconductor device, such as of HAR structures, in the distortion-corrected image; a determination of a line edge roughness in the distortion-corrected image; and/or a determination of an overlay error between different features in a semiconductor device in the distortion-corrected image. These example applications will be further described below in more detail.

It is possible that the extracted geometric characteristic of a feature 701 extends over a plurality of image subfields 31.mn and is thus divided into a respective plurality of parts. In such a case, the position or positions of each part of the extracted geometric characteristic is/are individually distortion-corrected based on the related individual vector distortion map 730 of the corresponding image subfield 31.mn of the respective part. This significantly enhances the accuracy of a measurement process, since the scanning induced distortion is not necessarily a smooth function over subfield boundaries 725.

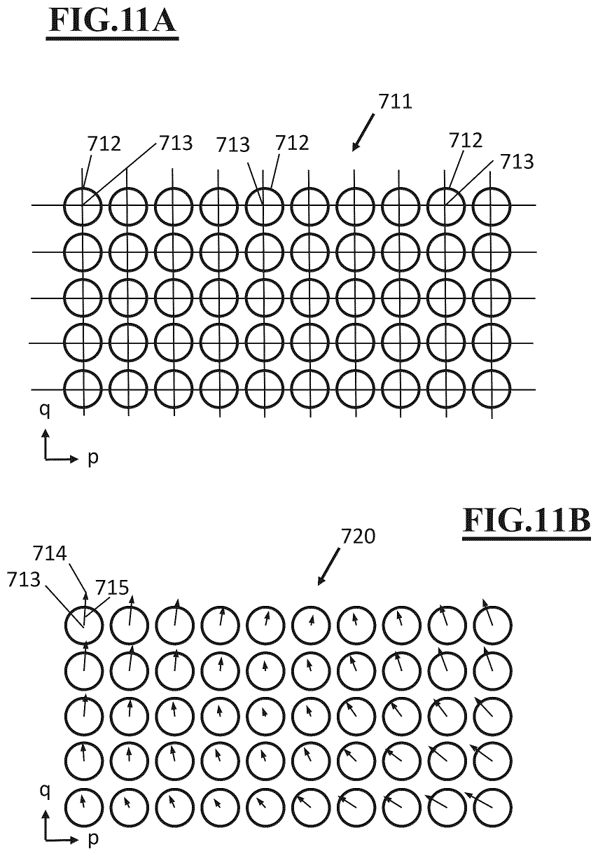

FIGS. 11A-11B is an illustration of the determination of a vector distortion map 730 based on a target grid 711. FIG. 11A shows a test sample with a precisely known and in this example repetitive pattern of structures 712 defining the target grid. In the present case, the target grid 711 comprises a plurality of circles. However, other target grids 711 can also be chosen, for example a target grid comprising squares or comprising a combination of squares and circles. The target grid is ideally a perfect grid with a nominal pitch between the plurality of structures 712 arranged in the regular pattern. The test sample is then imaged with a multi-beam charged particle microscope 1 and the obtained image is analyzed and an actual grid 720 is determined based on the analysis. The target grid 711 and the actual grid 720 differ from one another. The difference is described with respect to the center 713 of the structure 712 and is indicated with the help of a distortion vector 715 in FIG. 11B. The field of distortion vectors 715 is an example of the vector distortion map 730 used for distortion correction.

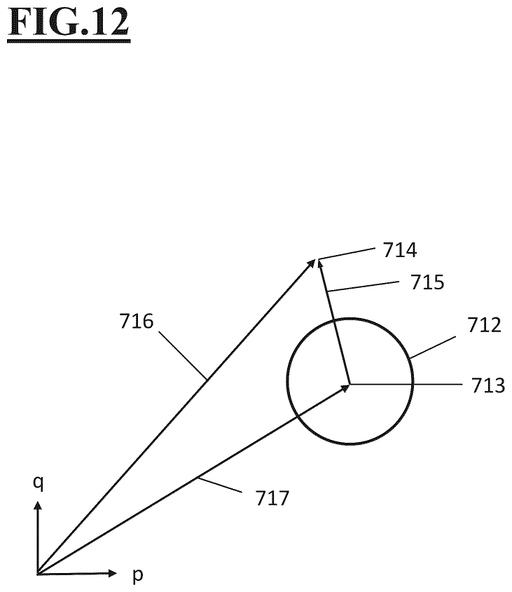

FIG. 12 is an illustration of the determination of a distortion vector 715. Vector 717 defined within the internal coordinate system with the coordinates p, q points towards the center 713 of the structure 712 of the ideal target grid 711. However, when determining the actual grid, this center 713 is imaged at position 714 which can be described by the vector 716 in terms of the internal coordinates p, q of the image subfield. Subtracting vector 717 from the vector 716 results in the distortion vector 715. It is noted that the distortion vector 715 can be defined as a vector pointing from the origin of the ideal grid 713 to the actually measured center of the grid 714. However, in general, it is also possible to define the distortion vector 715 as the inverse to the presently depicted vector. Depending on the definition, it is either the distortion vector 715 as such or its inverse that is used for correcting the position or positions of the extracted geometric characteristic in the image subfield 31.mn.

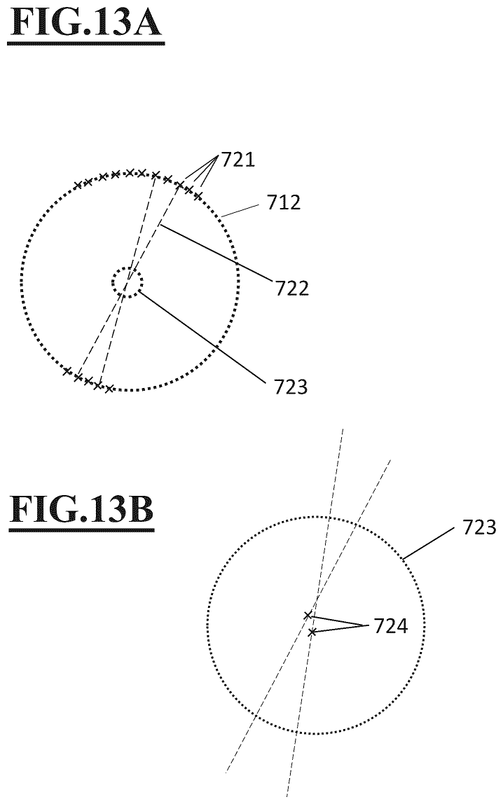

FIGS. 13A-13B illustrate the determination of a grid point in the actual grid 720. The target grid 710 comprises a plurality of regular and highly precisely known structures 712. These structures 712 have an ideal contour. In the depicted example, the structure 712 is a circle. When the test sample is imaged, several single contour positions 721 are determined. Due to the geometric properties of the structure 712 which is point symmetric in the present case, a connection line 722 connecting two edge positions on opposite sides of the structure 712 can be defined. Reference sign 723 indicates a region of line midpoints 724 containing the structure center 713. The structure center 713 is used for defining a grid position. The average position of these midpoints 724 can be used as the actual structure center say the structure center with respect to the actual grid 720. The standard deviation of the midpoint positions 724 is a measure of how precise or reliably the feature center 713 can be determined. If this deviation is too large, the structure can be excluded from further processing.

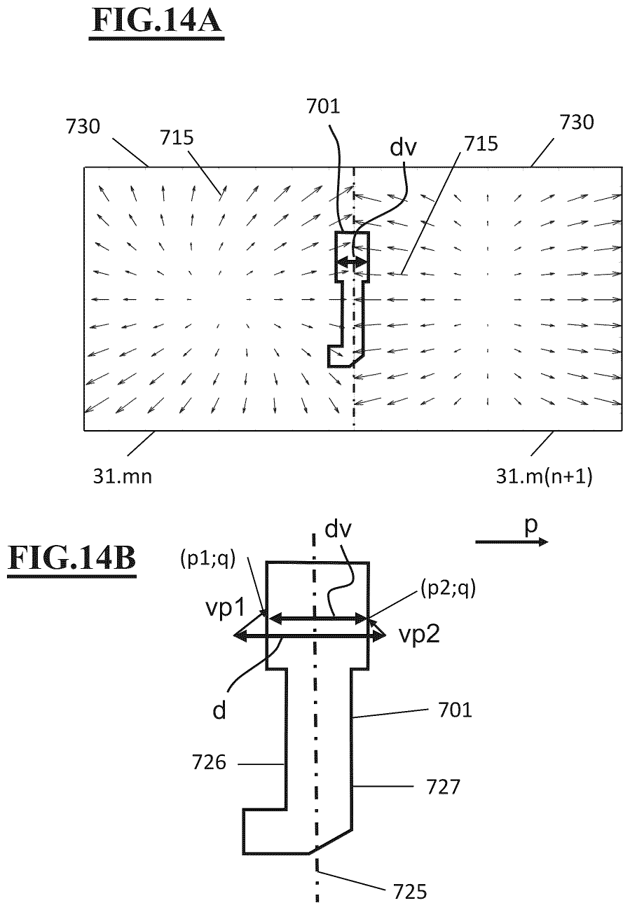

FIGS. 14A-14B is an illustration of a dimension measurement based on the distortion-corrected geometry data. FIG. 14A exemplarily shows two image subfields 31.mn and 31.m (n+1) with their corresponding vector distortion maps 730 comprising a field of distortion vectors 715. In conventional, single-beam charged particle microscopes with a single image field, distortion is a slowly varying, continuous function over the single image field and has only a negligible impact on measurement of dimensions. However, in a multi-beam charged particle microscope with a plurality of image subfields 31.mn as for example the subfields 31.mn and 31.m (n+1), the overall distortion is a discontinuous function at a subfield boundary 725. A dimension measurement of a feature 701 which extends over the two image subfields 31.mn and 31.m (n+1) can therefore be deteriorated by the large difference of the discontinuous distortion function. According to the present disclosure, the two parts 726 and 727 of the feature 701 are distortion-corrected separately and in accordance to the vector distortion maps 730 of the respective image subfields 31.mn and 31.m (n+1). In more detail, the geometric characteristic of the feature that is extracted from the image is the distance dv, more precisely the two positions (p1;q) and (p2;q) wherein the value of q is identical and is therefore not further illustrated. However, the coordinate (p1;q) is determined with respect to the image subfield 31.mn whereas the coordinate (p2;q) is determined with respect to the image subfield 31.m (n+1). The position of (p1;q) is corrected based on the vector distortion map 730 of the image subfield 31.mn and the position of (p2;q) is corrected based on the vector distortion map 730 of image subfield 31.m (n+1). The respective distortion vectors vp1 and vp2 are also illustrated in FIG. 14B. As a result, the distance dv is distortion corrected to the distance d.

FIGS. 14A-14B illustrates the situation, when the static distortion of the plurality of primary beamlets is compensated. Therefore, the vector distortion maps 730 at the center positions of the respective image subfield 31.mn, 31.m (n+1) show no distortion or offset of the distortion vectors. It is however also possible that each of the vector distortion maps 730 according the scanning induced distortion of an image subfield 31.mn, 31.m (n+1) comprises an additional offset distortion vector, arising from a static distortion of the multi-beam charged particle system 1. Each distortion vector offset of each image subfield can be different, as illustrated for example in FIG. 3.

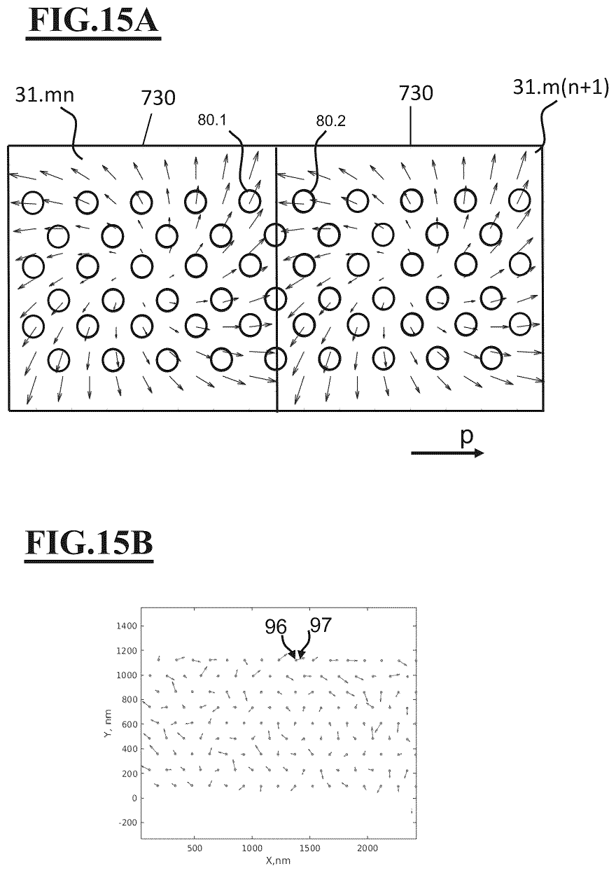

FIGS. 15A-15B illustrate a statistical evaluation of the positions of regular objects based on distortion-corrected image data. FIG. 15A depicts a plurality of HAR features wherein reference signs 80.1 and 80.2 label a first HAR structure and a second HAR feature, respectively. These HAR features 80.1, 80.2 can for example be identified by pattern recognition that is in general well-known. Pattern recognition can for example be assisted by machine learning. The geometric characteristic of the HAR features 80.1 and 80.2 is in each case the center position of the HAR features 80.1 and 80.2. The center position of each HAR structure 80 is extracted and its position is determined. Furthermore, it is determined to which image subfield 31.mn the center position of the HAR structure 80 belongs: In the present case, the center of the HAR structure 80.1 belongs to the image subfield 31.mn and the center of the HAR structure 80.2 belongs to the image subfield 31.m (n+1). Then, the positions of the centers of the HAR structures 80.1 and 80.2 are corrected based on the corresponding vector distortion map 730 of the corresponding image subfield 31.mn and 31.m (n+1), respectively. The corrected center positions can then be analyzed and for example be compared to design center positions 96 of the plurality of HAR structures and the deviations 97 from the designed center positions 96 are analyzed. Also, in the example depicted in FIGS. 15A-15B, it is important that first of all the feature extraction and position or measurement is carried out in the still distorted binary image. Afterwards, the distortion correction is carried out in a positioned dependent way and with respect to a related image subfield 31.mn, 31.m (n+1).

In addition to the concrete applications depicted in FIGS. 14A-14B and FIGS. 15A-15B, several other applications of the present disclosure are possible. One of them is the LER-determination (line edge roughness determination) across a subfield boundary 725. The distortion discontinuity across the subfield boundary 725 can generate a discontinuity in a line itself. A possible solution according to the present disclosure is basically to extract the line first, to divide the line into parts belonging to different image subfields, to apply the distortion correction to each part of the line and then to determine the line edge roughness.

A deviation of a position of the first feature 701 of a first layer to a second feature 701′ of a second layer is called an overlay error. Overlay errors can be determined at features 701, 701′ which are generated in different lithography steps or in different layers. Once again, according to the present disclosure, the features 701, 701′ are extracted first. Afterwards, a distortion correction is applied to the features 701, 701′. The disclosure is of special importance when the first feature 701 and the second feature 701′ are within different image subfields 31.mn.

It is a general task of the disclosure to reduce or avoid distortion compensation during image postprocessing of 2D image data. As described above, distortion compensation during post processing of 2D image data involves storing the source image data and computing distortion corrected target image data. According to the improved method of distortion correction provided above, a distortion correction is performed on a reduced set of extracted parameters such as edges or center positions and not on full scale 2D pictures data. Thereby, the computational effort and power consumption is reduced by at least one order of magnitude or even up to five orders of magnitudes. According to a further embodiment of the disclosure, the desired computational effort and power consumption of postprocessing is even further reduced. In this embodiment, the digital image data stream received from the image sensor 207 is directly written to a memory 814 such that distortion aberrations are reduced or compensated during the processing of the data stream. At least a major part of the distortion of each subfield 31.mn can thus be compensated during the stream processing.

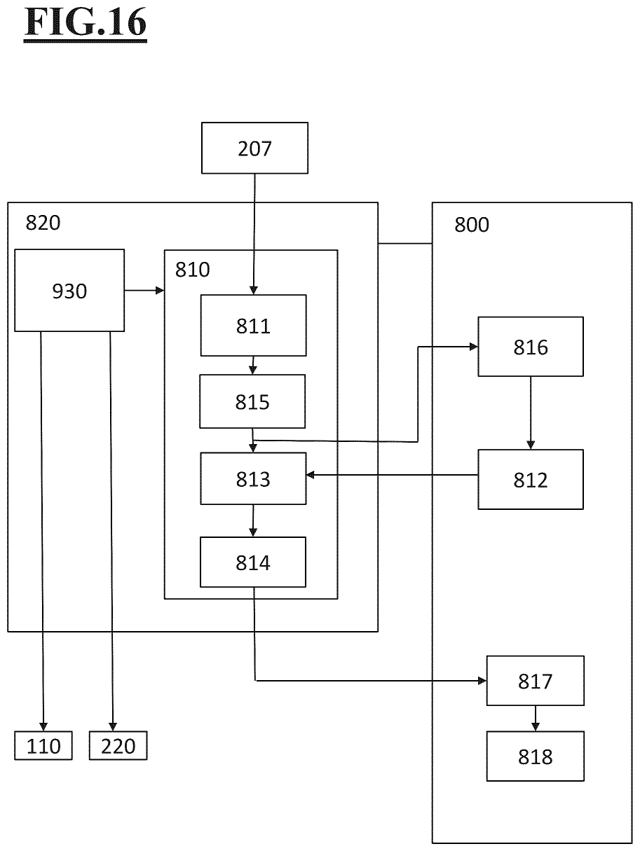

FIG. 16 is an illustration of an image data acquisition unit 810 and related units or modules. For ease of illustration, only one image channel is depicted; remaining image channels are not illustrated in FIG. 16. The number of image channels corresponds in the present case to the number of J beamlets applied for imaging with the multi-beam charged particle microscope 1.

In an example, an image sensor 207 comprises a plurality of J photodiodes corresponding to the plurality of J secondary electron beamlets. Each of the J photodiodes, for example Avalanche photodiodes (APD), is connected to an individual analog-to-digital converter. The image sensor can further comprise an electron-to-photon converter, as for example described in DE 102018007455 B4, which is hereby fully incorporated by reference.

The analog-to-digital converters 811 convert the analog data streams into a plurality of J digital data streams. After conversion into a digital data stream, the data is provided to the averaging unit 815; however, the averaging unit 815 can also be omitted. In general, pixel averaging or line averaging can be carried out; for more detailed information reference is made to WO 2021/156198 A1, which is hereby fully incorporated by reference.

The image data acquisition unit comprises for each of the J image subfields a hardware filter unit 813. This hardware filter unit 813 is configured to receive a digital data stream and is configured for carrying out during use of the multi-beam charged particle microscope 1 a convolution of a segment of the image subfield 32.mn with the space variant filter kernel 910, thus generating a distortion-corrected data stream. The details of this distortion correction will be described in greater depth below.

The image data acquisition unit 810 further comprises an image memory 814 configured for storing the distortion-corrected data stream as a 2D representation of the image subfield 31.mn.

In the depicted example, the image data acquisition unit 810 is part of an imaging control module 820 which also comprises a scan control unit 930. In the present example, the scan control unit 930 is configured for controlling the first collective raster scanner 110 as well as the second collective raster scanner 220. It is also possible that further control mechanisms of the scan control unit 930 are implemented within the multi-beam charged particle microscope 1, not shown in FIG. 16.

In general, the overall control of the multi-beam charged particle microscope 1 comprises different units or modules. However, it is to be born in mind that the depicted representation of different modules belonging to the control could also be chosen and realized in a different way; the structure depicted in FIG. 16 is thus only an example. In addition to the imaging control module 820, a control unit 800 is provided. The image memory 814 is connected for parallel readout to the control unit 800 which is configured to read out the plurality of J digital images corresponding to the J image subfields 31.11 to 31.mn. An image stitching unit 817 of the control unit 800 is configured to stitch the J digital image subfields to one digital image file corresponding to one image patch, for example image patch 17.k. The image stitching unit 817 is connected to the image data processor and output 818, which is configured to extract information from the digital image file and is configured to write the digital image file to a memory or to provide information from the digital image file to a display.

It is noted that the modules and processes illustrated in FIG. 16 are precisely synchronized which can be realized by the provision of appropriate clock signals (not further illustrated in FIG. 16). Additionally, since the hardware filter unit 813 is configured for carrying out a convolution of a segment of the image subfield with a space variant filter kernel 910, a counting unit 816 is implemented within the control unit 800 which provides input to the kernel generating unit 812 which provides the data for the filter kernel to the hardware filter unit 813. Once again, it shall be stressed that a filter kernel 910 is calculated for each imaging channel; however, this plurality of imaging channels is not further illustrated in FIG. 16 for ease of illustration purposes.

The imaging control module 820 of a multi-beam charged particle microscope 1 can comprise a plurality of L image data acquisition units 810.n, comprising at least a first image data acquisition unit 810.1 and a second image data acquisition unit 810.2 arranged in parallel. Each of the image data acquisition units 810.n can be configured to receive the sensor data of image sensor 207 corresponding to a subset of S beamlets of the plurality of J primary charged particle beamlets and produce a subset of S streams of digital image data values of the plurality of J streams of digital image data values. The number of S beamlets attributed to each of the L image data acquisition units 810.n can be identical and S×L=J. The number of S is for example between 6 and 10, for example S=8. The number L of parallel image data acquisition units 810.n can for example be 10 to 100 or more, depending on the number J of primary charged particle beamlets. By the modular concept of the imaging control module 820, the number J of charged particle beamlets in a multi-beam charged particle microscope 1 can be increased by the addition of parallel image data acquisition units 810.n.

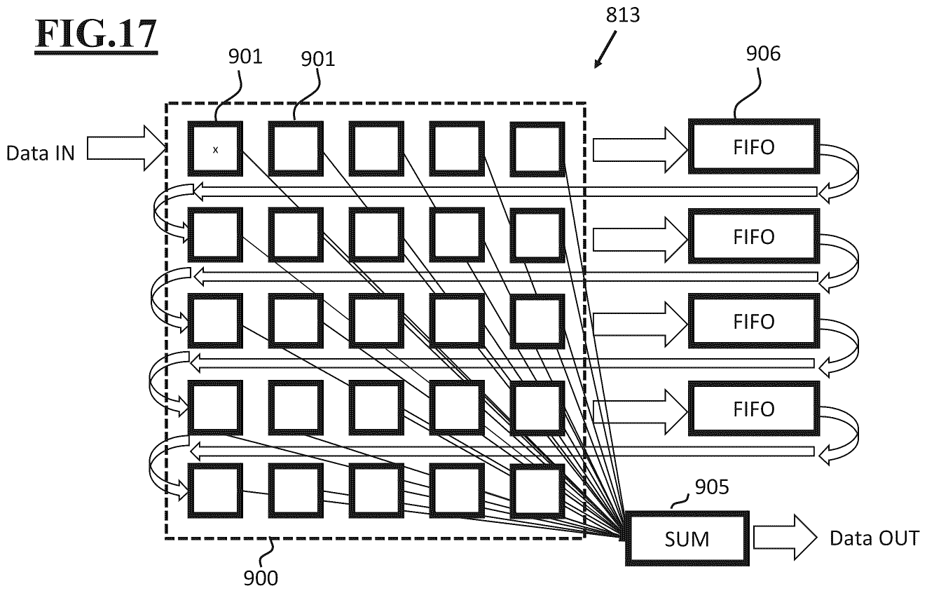

FIG. 17 is an illustration of the hardware filter unit 813. An arrow in FIG. 17 illustrates the data input into the hardware filter unit 813. In the depicted embodiment, the hardware filter unit 813 comprises a grid arrangement 900 with 5×5 filter elements 901. The grid arrangement 900 of filter elements 901 shall reflect or shall be equivalent to a representation of a segment of an image subfield 31.mn. Therefore, the order and arrangement of data within the grid arrangement 900 is of importance to ensure this relationship or equivalence. In the exemplary embodiment, the hardware filter unit 813 is realized by a sequence of FIFOs 906. The sequence of FIFOs 906 ensures to maintain the order of data entering the hardware filter unit 813. Furthermore, the FIFOs 906 ensure to correctly jump from the first row or line of the image subfield 31.mn to the second row or line of the image subfield etc. Therefore, when stepwise filling the filter elements 901 with pixel values and passing the sequence of pixel values through the filter unit 813, entries of pixel values within the grid arrangement 900 can correspond to a segment of the image subfield 31.mn to be distortion corrected.

As already mentioned before, the hardware filter unit 813 is configured for carrying out a convolution of the segment 32 of an image subfield 31.mn with a space variant filter kernel 910. In other words, the values or coefficients of the filter kernel 910 have to be individually calculated for a filtering process of a specific segment 32 being filtered. Each filter element 901 within the depicted grid arrangement 900 comprises entries of two kinds: the pixel value as such and a coefficient generated by the kernel generating unit. For the convolution to be carried out, a multiplication of entries within the filter elements 901 is to be carried out. Afterwards, the results of this multiplication have to be summed up which is indicated by the lines in FIG. 17 connecting the filter elements 901 with the box 905. The filter operations carried out (the multiplications and the summations) result in a time delay which stays constant during the whole filtering process of the entire image subfield 31.mn. The distorted data stream (data IN) is transformed into a distortion-corrected data stream (data OUT).

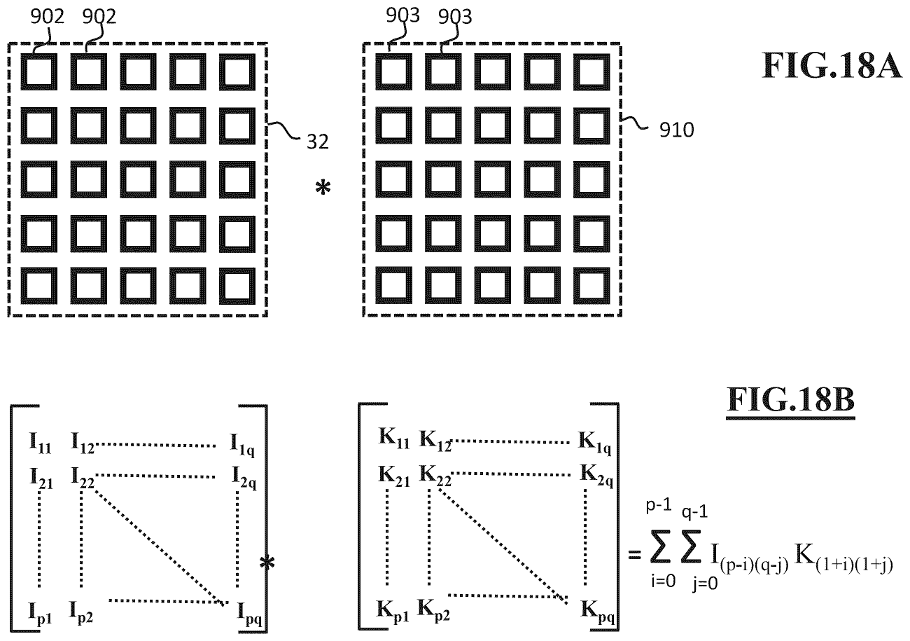

FIGS. 18A-18B is an illustration of a convolution of a segment 32 of an image subfield 31.mn with a filter kernel 910. The segment 32 of the image subfield 32.mn and the filter kernel 910 are both depicted as a grid arrangement of a filter element 901 and the size of the filter kernel 910 is identical in the present case. Here, a 5×5 realization is depicted. On the left side of FIG. 18A, uncorrected pixel values or intensities I are depicted in first registers 902. Within the filter kernel 910, a plurality of coefficients 903 generated by the kernel generating unit 812 are stored in second registers 903.

FIG. 18B shows the mathematical equivalent to the situation shown in FIG. 18A: Depicted are two matrices that have to be convoluted. The result is a double sum over certain products of matrix entries with one another. Normally, it is to be noted that different entries of the matrices have to be multiplied with one another, for example it is normally not the entry I₁₁ and the entry K₁₁ that have to be multiplied with one another. This is only the case for a symmetric filter kernel. However, there still exists a fixed scheme according to which different entries have to be multiplied. This scheme can also be already implemented by the respective hardware representation of the filter kernel 910 (flipping process of both the rows and columns of the kernel).

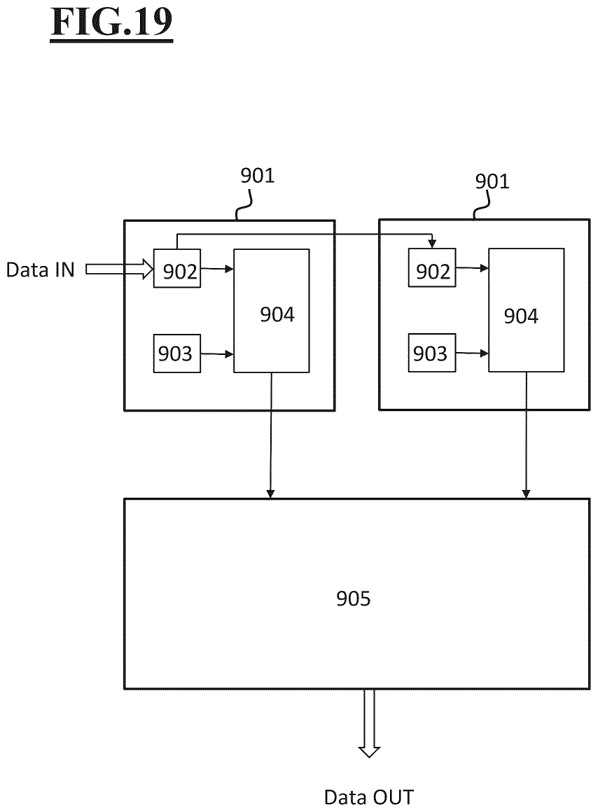

FIG. 19 is an illustration of an excerpt of filter elements 901 and related elements. In more detail, according to the depicted embodiment, each filter element 901 comprises a first register 902 temporarily storing a pixel value and a second register 903 temporarily storing a coefficient generated by the kernel generating unit 812. Furthermore, the filter element 901 comprises a multiplication block 904 configured for multiplying the pixel value stored in the first register 902 with the corresponding coefficient stored in the second register 903. It is noted that the multiplication blocks 904 are not necessarily part of the filter elements 901 as such, but they can also be realized separately. After the multiplication is carried out with a multiplication block 904, the respective result is presented to the summation block 905. FIG. 19 only shows two filter elements 901 and one summation block 905; it is noted that normally more filter elements 901 and a plurality of summation blocks 905 are provided for successfully realizing a distortion correction. The arrows in FIG. 19 indicate the data flow. Furthermore, the entries in the second registers 903 are provided by the kernel generating unit 812 (not illustrated in FIG. 19).

According to a more general embodiment, the hardware filter unit 813 can comprise a grid arrangement 900 of filter elements 901, each filter element 901 comprising a first register 902 temporarily storing a pixel value and a second register 903 temporarily storing a coefficient generated by the kernel generating unit 812, the pixel values temporarily stored in the first registers 902 representing a segment of the image subfield 31.mn. The hardware filter unit 813 can furthermore comprise a plurality of multiplication blocks 904 configured for multiplying pixel values stored in the first registers 902 with the corresponding coefficients stored in the second registers 903. The hardware filter unit 813 can furthermore comprise a plurality of summation blocks 905 configured for summing up the results of the multiplications. According to this more general formulation, the number of multiplication blocks is not necessarily identical to the number of filter elements 901, but can be reduced.

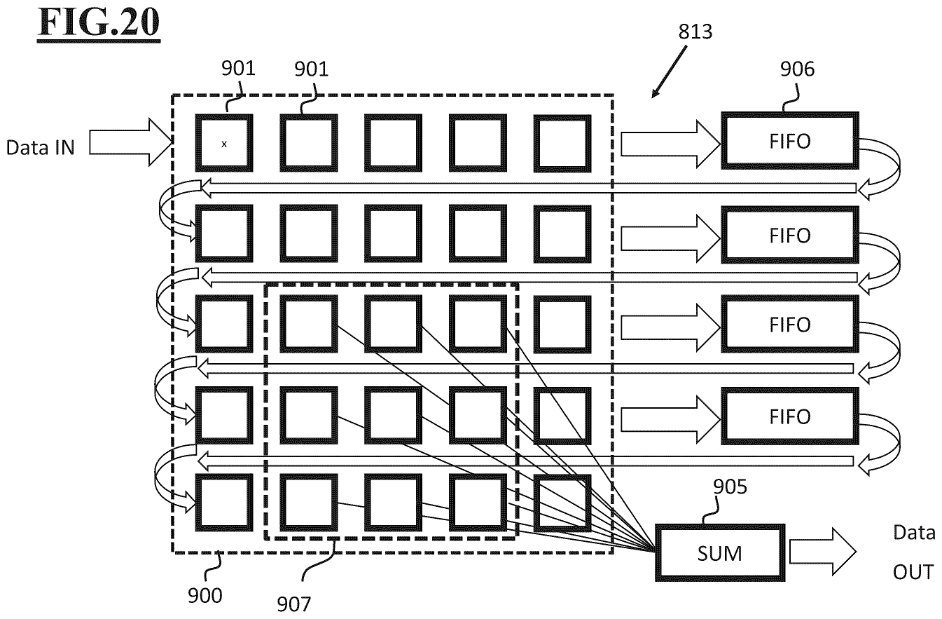

The latter situation is illustratively depicted in FIG. 20: FIG. 20 is an illustration of a hardware filter unit 813 with a 3×3 filter kernel window. Thus, the filter kernel window (3×3) is smaller than the grid arrangement 900 (5×5). Here, it is important that the filtering process according to the present disclosure is carried out for a specific purpose, namely distortion correction. A distortion correct can be interpreted as a shift of a pixel. This means that even if a full convolution of a full-size kernel filter 910 with the pixel values stored in the first registers 902 of the filter elements 901 is carried out, there are numerous multiplications that do not have an effect on the result of the distortion correction and more precisely on the generated sum. Therefore, it does not make a difference for the result (the summation) if all filter elements 901 are considered in the convolution. Instead, it is of importance that the relevant filter elements 901 are chosen for the calculation processes. This choice can be made by choosing an appropriate kernel window 907. Of course, it is not arbitrary where exactly the filter window 907 is positioned within the grid 900. The position of the kernel window 907 can be determined by the kernel generating unit 812, such as “on the fly”. If this embodiment variant is chosen, it is not necessary to provide a multiplication block for each of the filter elements 901. It is therefore possible to reduce the number of logical units within the hardware filtering unit 813. However, because the position of the kernel window 907 is not fixed for each segment 32 of the image subfield 31.mn, the possibilities for carrying out different multiplications is desirably guaranteed. Therefore, a plurality of switching mechanisms is provided which are configured for during use logically combining entries and filter elements 901 with multiplication blocks 904 based on the position of the kernel window 907.

According to an embodiment, the kernel generating unit 812 is configured to determine the space variant filter kernel 910 based on a vector distortion map 730 characterizing the space variant distortion in an image subfield 31.mn. According to an embodiment, the vector distortion map 730 is described by a polynomial expansion in vector polynomials. Alternatively, the vector distortion map 730 is described by a multi-dimensional look-up table. Furthermore, the kernel generating unit 812 can be configured to determine the filter kernel 910 based on a function f representatively describing a pixel. Possible functions f for describing a pixel can for example be a Rect2D function describing a rectangular pixel. Alternatively, the shape of a beam focus of a pixel can be taken as a function f, for example a Gauss function, an anisotropic function, a cubic function, a sinc function, an airy-pattern etc., the filter being truncated at some low-level value. Furthermore, the filters should be energy conserving, thus higher order, truncated filter kernels 910 should be normalized to a sum of weights equaling one.

As already explained with respect to FIG. 7 of the present patent application, a pixel 700 is “distributed” over four pixels 700′ in the distortion-corrected image. Therefore, a kernel window 907 of just the size 2×2 can be applied.

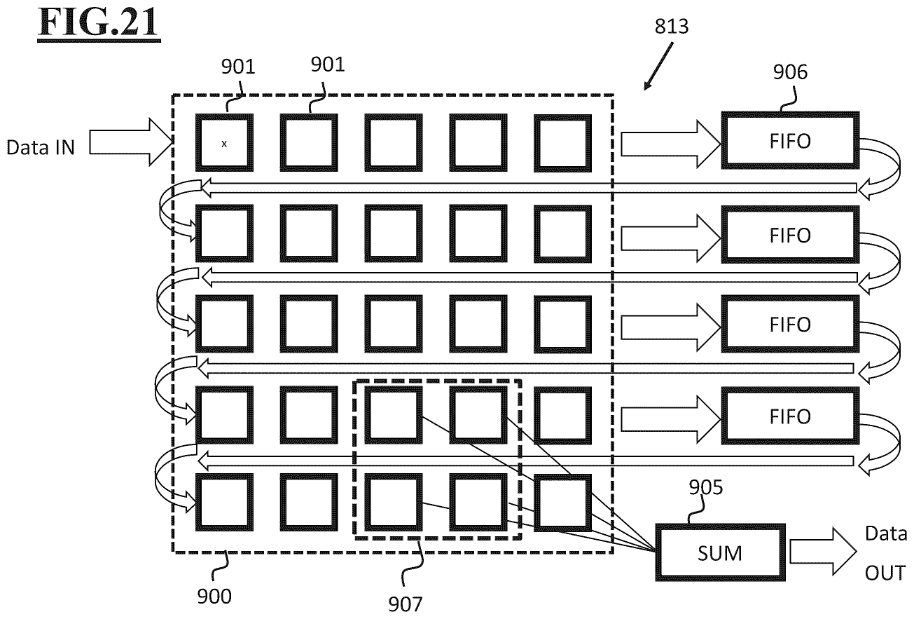

FIG. 21 is an illustration of the hardware filter unit 813 with just a 2×2 filter kernel window 907. The illustration depicted in FIG. 21 corresponds to the shift illustrated in FIG. 7 of the present patent application.

With the embodiments of the disclosure, a distortion compensation during image post-processing of 2D image data is minimized or avoided. Accordingly, no distortion correction per pixel of huge 2D images comprising several giga-pixel and involving large amounts of image memory, is involved. Instead, for example, a distortion correction is performed to a reduced set of extracted parameters such as edges or center positions and not to full scale 2D image data. According to a further example, the distortion of each subfield 31.mn is compensated during the stream processing of the data stream from the image sensor 207. A stream processing of the analogue data from the image sensor 207 is used anyway, and an additional distortion compensation during the stream processing only involves little additional computation power and a reduced amount of additional memory. By the disclosure, the computational effort and power consumption is thereby reduced by at least one order of magnitude or even up to five orders of magnitudes. It is also possible to combine the two methods and configurations. In an example, it is advantageous to compensate a first part of vector distortion polynomials for each image subfield 31.mn by stream processing, and a second part of vector distortion polynomials via distortion correction at the reduced set of extracted parameters or geometric characteristics. For example, the linear parts of the distortion polynomial are compensated during stream processing, and higher order distortions are compensated via distortion correction at the reduced set of extracted parameters. Thereby, the additional computational effort of computing higher order vector polynomials during stream processing is reduced. In general, the disclosure allows a distortion correction for a multi-beam charged particle inspection system 1 with reduced amount of computational power and reduced amount of energy consumption. The disclosure thereby enables inspection tasks or metrology tasks during semiconductor fabrication processes with high efficiency and reduced computational effort and reduced energy consumption.

It is noted that the embodiments of the disclosure described with reference to the figures are not meant to be limiting for the present disclosure. The figures only show possible implementations of the disclosure.

In the following, further examples of the disclosure are described. They can be combined with other embodiments and examples as described above.

Example 1. Method for determining a distortion-corrected position of a feature in an image that is composed of one or a plurality of image patches, each image patch being composed of a plurality of image subfields, each image subfield being imaged with a related beamlet of a multi-beam charged particle microscope, respectively, the method comprising the following steps:
a) Providing a plurality of vector distortion maps for each image subfield, respectively, each vector distortion map characterizing the position dependent distortion for each pixel of the related image subfield;
b) Identifying a feature of interest in the image;
c) Extracting a geometric characteristic of the feature;
d) Determining a corresponding image subfield comprising the extracted geometric characteristic of the feature;
e) Determining a position or positions of the extracted geometric characteristic of the feature within the determined corresponding image subfield; and
f) Correcting the position or positions of the extracted geometric characteristic in the image based on the vector distortion map of the corresponding image subfield, thus creating distortion-corrected image data.

Example 2. The method according to example 1, wherein the method steps b) to f) are carried out repeatedly for a plurality of features.

Example 3. The method according to any one of the preceding examples, wherein other areas in the image not comprising any features of interest are not distortion-corrected.

Example 4. The method according to any one of the preceding examples, wherein the geometric characteristic of the feature is at least one of following: a contour, an edge, a corner, a point, a line, a circle, an ellipse, a center, a diameter, a radius, a distance.

Example 5. The method according to any one of the preceding examples, wherein extracting a geometric characteristic comprises the generation of binary images.

Example 6. The method according to any one of the preceding examples,
wherein the extracted geometric characteristic of a feature extends over a plurality of image subfields and is thus divided into a respective plurality of parts, and
wherein the position or positions of each part of the extracted geometric characteristic is/are individually corrected based on the related individual vector distortion map of the corresponding image subfield of the respective part.

Example 7. The method according to any one of the preceding examples, wherein extracting geometric characteristics of features of interest is carried out for the entire image.

Example 8. The method according to any one of the preceding examples, wherein correcting the position or positions of the extracted geometric characteristic in the image based on the vector distortion map of the corresponding image subfield comprises determining a distortion vector for at least one position of the extracted geometric characteristic.

Example 9. The method according to any one of the preceding examples, wherein correcting a position or positions of the extracted geometric characteristic in the image based on the vector distortion map of the corresponding image subfield comprises converting a pixel of the image into at least one pixel of the distortion-corrected image based on the distortion vector.

Example 10. The method according to any one of the preceding examples, wherein each of the plurality of vector distortion maps is described by a polynomial expansion in vector polynomials.

Example 11. The method according to any one of examples 1 to 9, wherein each of the plurality of vector distortion maps is described by 2-dimensional look-up tables.

Example 12. Method according to any one of the preceding examples, further comprising at least one of the following steps:
determining a dimension of a structure of a semiconductor device in the distortion-corrected image data;
determining an area of a structure of a semiconductor device in the distortion-corrected image data;
determining positions of a plurality of regular objects in a semiconductor device, in particular of HAR structures, in the distortion-corrected image data;
determining a line edge roughness in the distortion-corrected image data; and/or determining an overlay error between different features in a semiconductor device in the distortion-corrected image data.

Example 13. The method according to any one of the preceding examples, further comprising the following steps:
providing a test sample with a precisely known and in particular repetitive pattern defining a target grid;
imaging the test sample with the multi-beam charged particle microscope, analyzing the obtained image and determining an actual grid based on the analysis;
determining positional deviations between the actual grid and the target grid; and
obtaining the vector distortion map for each image subfield based on the positional deviations.

Example 14. The method according to the preceding example, further comprising shifting of the test sample from a first position to a second position with respect to the multi-beam charged particle microscope and imaging the test sample in the first position and in the second position.

Example 15. The method according to any one of examples 13 to 14, wherein determining positional deviations comprises a two-step determination, wherein in a first step a shift of each image subfield, a rotation of each image subfield and a magnification of each subfield are compensated and wherein in a second step the remaining higher-order distortion is determined.

Example 16. The method according to any one of the preceding examples, further comprising the following step:
updating the vector distortion map.

Example 17. The method according to any one of the preceding examples, further comprising the following step:
Correcting a distortion in the image by stream-processing of data during image pre-processing.

Example 18. Method for correcting the distortion in an image that is composed of one or a plurality of image patches, each image patch being composed of a plurality of image subfields, each image subfield being imaged with a related beamlet of a multi-beam charged particle microscope, respectively, the method comprising the following steps:
g) Providing a plurality of vector distortion maps for each image subfield, respectively, each vector distortion map characterizing the position dependent distortion for each pixel of the related image subfield;
h) For each pixel in the image: determining a corresponding image subfield comprising the pixel; and
i) For each pixel in the image: converting the pixel in the image into at least one pixel in the distortion-corrected image based on the vector distortion map of the corresponding image subfield.

Example 19. Computer program product comprising a program code for carrying out the method according to any one of the preceding examples 1 to 18.

Example 20. Multi-beam charged particle microscope with a control configured for carrying out the method as described in any one of examples 1 to 18.

### LIST OF REFERENCE SIGNS

1 multi-beamlet charged-particle microscopy system
3 primary charged particle beamlets, forming the plurality of primary charged particle beamlets
5 primary charged particle beam spot
7 object
9 secondary electron beamlet, forming the plurality of secondary electron beamlets
11 secondary electron beam path
13 primary beam path
15 secondary charged particle image spot
17 image patch
19 overlap area of image patches
21 image patch center position
25 Wafer surface
27 scanpath of primary beamlet
29 center of image subfield
31 image subfield
32 segment of an image subfield
33 first inspection site
35 second inspection site
39 overlap areas of subfields 31
80.1 HAR structure
80.2 HAR structure
96 design center position of HAR structure
97 deviation from design center position of HAR structure
100 object irradiation unit
101 object or image plane
102 objective lens
103 field lens group
105 optical axis of multi-beamlet charged-particle microscopy system
108 first beam cross over
110 first multi-beam raster scanner
112 correction elements of multi-beam raster scanner
120 scanning correction control module
141 example of a primary beam spot position
143 static displacement vector of the primary beam spot
150 center beamlet
151 real beamlet trajectory
153 Deflector electrodes
155 equipotential lines of the electrostatic potential
157 off axis or field beamlet
159 virtual common pivot point
161 virtual pivot points
163 first order beam paths
171 system upfront scanner 110
189 intersection volume of traversing beams
200 detection unit
205 projection system
206 electrostatic lens
207 image sensor
208 imaging lens
209 imaging lens
210 imaging lens
212 second cross over
214 aperture filter
216 active element
218 third deflection system
220 multi-aperture corrector
222 second deflection system
300 charged-particle multi-beamlet generator
301 charged particle source
303 collimating lenses
305 primary multi-beamlet-forming unit
306 active multi-aperture plates
307 first field lens
308 second field lens
309 electron beam
311 primary electron beamlet spots
321 intermediate image surface
390 beam steering multi aperture plate
400 beam splitter unit
420 magnetic element
500 sample stage
503 sample voltage supply
700 pixel
701 feature
702 greyscale image
710 binary image
711 target grid
712 structure
713 center of the structure
714 point of actual grid
715 distortion vector
716 vector
717 vector
720 actual grid
721 single contour position
722 connection line connecting two edge positions on opposite sides of the structure
723 region of line midpoints containing the structure center
724 line midpoints
725 subfield boundary
726 first part of feature
727 second part of feature
730 vector distortion map
800 control unit
810 image data acquisition unit
811 analogue to digital converter
812 kernel generating unit
813 hardware filter unit
814 image memory
815 averaging unit
816 counting unit
817 image stitching unit
818 image processing and output
820 projection system control module, imaging control module
830 primary beam path control module
900 grid arrangement
901 filter elements
902 first register storing pixel value
903 second register storing coefficient
904 multiplication block
905 summation block
906 shifting register
907 kernel window
910 filter kernel
930 scan control unit
S1 Providing a plurality of vector distortion maps for each image subfield, respectively
S2 Identifying a feature of interest in the image
S3 Extracting a geometric characteristic of the feature
S4 Determining a corresponding image subfield comprising the extracted geometric characteristic of the feature
S5 Determining a position or positions of the extracted geometric characteristic of the feature within the corresponding image subfield
S6 Correcting the position or the positions of the extracted geometric characteristic in the image based on the vector distortion map of the corresponding image subfield, thus creating distortion-corrected image data
S7 end or further method steps
dv distance in distorted image
d distance in distortion corrected image
vp1 distortion vector first part
vp2 distortion vector second part
p internal coordinate of image subfield
q internal coordinate of image subfield
x global coordinate
y global coordinate

What is claimed is:

1. A multi-beam charged particle microscope, comprising:
a first collective raster scanner configured to collectively scan a plurality of primary charged particle beamlets over a plurality of image subfields;
a detection unit comprising a detector configured to detect a plurality of secondary electron beamlets, each secondary beamlet corresponding to one of the image subfields; and
a control comprising:
a scan control unit connected to the first collective raster scanner to control a raster scanning operation of the plurality of primary charged beamlets performed by the first collective raster scanner;
a kernel generating unit configured so that, for each image subfield, the kernal generating unit generates a space variant filter kernel for space variant distortion correction of the image subfield; and
an image data acquisition unit configured so that operation of the image data acquisition unit is synchronized with operation of the detector, the scan control unit and the kernel generating unit,
wherein, for each image subfield, the image data acquisition unit comprises:
an analogue to digital converter configured to convert an analogue data stream received from the detector into a digital data stream describing the image subfield;
a hardware filter unit configured to receive the digital data stream and to convolute a segment of the image subfield with the space variant filter kernel to generate a distortion-corrected data stream; and
an image memory configured to store the distortion-corrected data stream as a 2D representation of the image subfield.

2. The multi-beam charged particle microscope of claim 1, wherein the hardware filter unit comprises:
a grid arrangement of filter elements, each filter element comprising a first register configured to temporarily store a pixel value and a second register configured to temporarily store a coefficient generated by the kernel generating unit, the pixel values stored in the first registers representing a segment of the image subfield;
a plurality of multiplication blocks configured so that, for each first register and corresponding second register, the multiplication blocks multiply pixel values stored in the first register by the corresponding coefficients stored in the second register; and
a plurality of summation blocks configured to sum results of the multiplications.

3. The multi-beam charged particle microscope of claim 2, wherein a size of the grid arrangement of filter elements is configured to correct a distortion of at least ten times the pixel size of the image subfield.

4. The multi-beam charged particle microscope of claim 2, wherein the grid arrangement of filter elements comprises at least 21×21 filter elements.

5. The multi-beam charged particle microscope of claim 2, wherein a size of a predetermined kernel window is at most a size of the grid arrangement of filter elements.

6. The multi-beam charged particle microscope of claim 5, wherein the kernel generating unit is configured to determine the kernel window with respect to the grid arrangement of the filter elements.

7. The multi-beam charged particle of claim 6, wherein the hardware filter unit further comprises a plurality of switching mechanisms configured to logically combine entries in filter elements with multiplication blocks based on the position of the kernel window.

8. The multi-beam charged particle microscope of claim 1, wherein the hardware filter unit comprises a plurality of shifting registers configured to realize the grid arrangement of filter elements and to maintain an order of data in the data stream when passing through the hardware filter unit.

9. The multi-beam charged particle microscope of claim 1, wherein the image data acquisition unit further comprises counters configured to indicate local coordinates of a pixel within an image subfield that is being filtered.

10. The multi-beam charged particle microscope of claim 1, wherein the kernel generating unit is configured to determine the space variant filter kernel based on a vector distortion map characterizing the space variant distortion in an image subfield.

11. The multi-beam charged particle microscope of claim 1, wherein the vector distortion map is describable by a polynomial expansion in vector polynomials.

12. The multi-beam charged particle microscope of claim 1, wherein the vector distortion map is describable by a multi-dimensional look-up table.

13. The multi-beam charged particle microscope of claim 1, wherein the kernel generating unit is configured to determine the filter kernel based on a function representatively describing a pixel.

14. The multi-beam charged particle microscope of claim 13, wherein the function is identical for different scanning directions or different for different scanning directions.

15. The multi-beam charged particle microscope of claim 1, wherein the image data acquisition unit further comprises an averaging unit implementable in a direction of the data stream after the analogue to digital converter and before the hardware filter unit.

16. The multi-beam charged particle microscope of claim 1, wherein the image data acquisition unit further comprises a further hardware filter unit configured to perform a further filter operation.

17. The multi-beam charged particle microscope of claim 1, wherein the hardware filter unit comprises a field-programmable gate array or an application-specific integrated circuit.

18. The multi-beam charged particle microscope of claim 1, wherein the hardware filter unit comprises a sequence of FIFOs.

19. The multi-beam charged particle microscope of claim 18, wherein the FIFOs are implementabled as BlockRAMs, LUTs or externally connected SRAM or DRAM.

20. A system, comprising:
a multi-beam charged particle microscope according to claim 1; and
an image postprocessing unit configured to perform a distortion correction of image data.
